(19) United States
(12) Patent Application Publication
(10) Pub. No.: US 2026/0293322 A1
(43) Pub. Date: Sep. 24, 2026

(54) Semiconductor Structure and Method Thereof

(71) Applicant: Taiwan Semiconductor Manufacturing Company, Ltd., Hsinchu (TW)

(72) Inventors: Huan-Neng Chen, Hsinchu (TW); Shao-Yu Li, Hsinchu (TW); Wei-Cheng Zeng, Hsinchu (TW); Shou Ming Liu, Hsinchu (TW)

(21) Appl. No.: 19/087,814

(22) Filed: Mar. 24, 2025

(51) Int. Cl. H10D 89/60; H01L 23/528

(52) U.S. Cl. CPC H10D 89/811; H10W 20/427

(57) ABSTRACT

Die-to-die input/output integrated circuit (IC) structures and methods are provided. An IC structure comprises a first ESD protection circuit region, a frontside interconnect structure, and backside interconnect structure. The first ESD protection circuit region is disposed between a first buffer circuit region and a second buffer circuit region along a first direction on a substrate. The frontside interconnect structure is disposed over the substrate and has a first frontside metal line extending in a first direction and a second frontside metal line extending in a second direction perpendicular to the first direction. The first ESD protection circuit protection region is electrically coupled to the first and second buffer circuit regions through the first frontside metal line.

### BACKGROUND

In 3D integrated circuit (3DIC) packages (e.g., Chip-on-Wafer-on-Substrate (CoWoS) packages, Integrated Fan-Out (InFO) wafer level packages, System on Integrated Chips (SoIC) packages, or the like), electromigration (EM) management in die-to-die input/output circuits for routing metal widths and vias is tailored to comply with electrostatic discharge (ESD) standards.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A illustrates a schematic block diagram of an IC device in accordance with some embodiments of the present disclosure.

FIG. 1B illustrates a schematic plan circuit diagram of a buffer circuit with an electrostatic discharge (ESD) protection circuit in accordance with some embodiments of the present disclosure.

FIG. 1C illustrates a schematic plan circuit diagram of a buffer circuit with an ESD protection circuit in accordance with some embodiments of the present disclosure.

FIG. 2A illustrates a top view layout pattern of an IC structure including a buffer circuit with an ESD protection circuit in accordance with some embodiments of the present disclosure.

FIG. 2B illustrates a top view layout pattern of an IC structure including a buffer circuit with an ESD protection circuit in accordance with some embodiments of the present disclosure.

FIG. 3A illustrates a schematic cross-sectional view of an IC structure including a buffer circuit with an ESD protection circuit in accordance with some embodiments of the present disclosure.

FIG. 3B-3K illustrate cross-sectional views of the IC structure obtained from reference cross-sections B1-B1′, B2-B2′, B3-B3′, B4-B4′, B5-B5′, and B6-B6′ in FIG. 2A in accordance with some embodiments of the present disclosure.

FIG. 4 illustrates a top view layout pattern of an IC structure including a buffer circuit with an ESD protection circuit over a substrate in accordance with some embodiments of the present disclosure.

FIG. 5A illustrates a top view layout pattern of an IC structure including a buffer circuit with an ESD protection circuit in accordance with some embodiments of the present disclosure.

FIG. 5B illustrates a top view layout pattern of an IC structure including a buffer circuit with an ESD protection circuit in accordance with some embodiments of the present disclosure.

FIG. 5C illustrates a schematic cross-sectional view of an IC structure including a buffer circuit with an ESD protection circuit in accordance with some embodiments of the present disclosure.

FIG. 5D-5H illustrate cross-sectional views of the IC structure obtained from reference cross-sections E1-E1′, E2-E2′, and E3-E3′ in FIGS. 5A and 5B in accordance with some embodiments of the present disclosure.

FIG. 6A illustrates a top view layout pattern of an IC structure including a buffer circuit with an ESD protection circuit in accordance with some embodiments of the present disclosure.

FIG. 6B illustrates a top view layout pattern of an IC structure including a buffer circuit with an ESD protection circuit in accordance with some embodiments of the present disclosure.

FIG. 6C illustrates a schematic cross-sectional view of an IC structure including a buffer circuit with an ESD protection circuit in accordance with some embodiments of the present disclosure.

FIG. 6D-6G illustrate cross-sectional views of the IC structure obtained from reference cross-sections F1-F1′ and F3-F3′ in FIGS. 6A and 6B in accordance with some embodiments of the present disclosure.

FIGS. 7A-7D illustrate a schematic plan circuit diagram of a buffer circuit with an ESD protection circuit in accordance with some embodiments of the present disclosure.

FIG. 8 illustrate a flowchart depicting a method of manufacturing a IC structure including a buffer circuit with an ESD protection circuit in accordance with some embodiments of the present disclosure.

FIG. 9 illustrate a flowchart depicting a method of discharging an electrostatic induced current in accordance with some embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in some various examples. This repetition is for the purpose of simplicity and clarity and does not in itself dictate a relationship between some various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the circuit. Some of the features described below can be replaced or eliminated for different embodiments. Although some embodiments are discussed with operations performed in a particular order, these operations may be performed in another logical order.

Electromigration (EM) management in die-to-die input/output (I/O) circuits, particularly for routing metal widths and vias, must comply with ESD standards to ensure reliability. For example, an integrated circuit (IC) typically includes an ESD protection circuit integrated into its I/O circuits. ESD currents are directed to the ESD protection circuit through a buffer circuit (or other ESD sacrifice circuits) and then dissipated upward through metallization layers disposed over functional devices of the IC (referred to as the frontside interconnect structure) to a PAD pin or metal pin. This configuration may establish a horizontal current path, which can lead to current crowding within the frontside interconnect structure. Moreover, the dual-purpose use of the frontside interconnect structure for both ESD current dissipation and signal transmission among the functional devices within the IC exacerbates horizontal current crowding during ESD events, resulting in electromigration/IR-drop (EMIR) issues and potential reliability failures.

An embodiment of the present disclosure involves dividing the buffer circuit into two sub-buffer circuit regions on a substrate, which are positioned on both sides of an ESD protection circuit region. This arrangement splits a single horizontal ESD current into two horizontal ESD currents, which reducing horizontal current crowding and mitigating EMIR issues.

In some embodiments, additional metallization layers can be introduced beneath the substrate, referred to as a backside interconnect structure. ESD currents can then be directed downward to the backside interconnect structure, eventually dissipating through a backside PAD pin. In this arrangement, signals between functional devices within the IC are transmitted through the frontside interconnect structure, while ESD currents can be dissipated through the backside interconnect structure, thereby mitigating current crowding in the frontside metallization layers.

In some embodiments, the ESD protection circuit can be divided into two sub-ESD protection circuit regions on the substrate, and the buffer circuit can be further divided into four sub-buffer circuit regions. Each of the sub-ESD protection circuit regions is positioned between two sub-buffer circuit regions. This configuration further reduces horizontal ESD currents of the frontside interconnect structure.

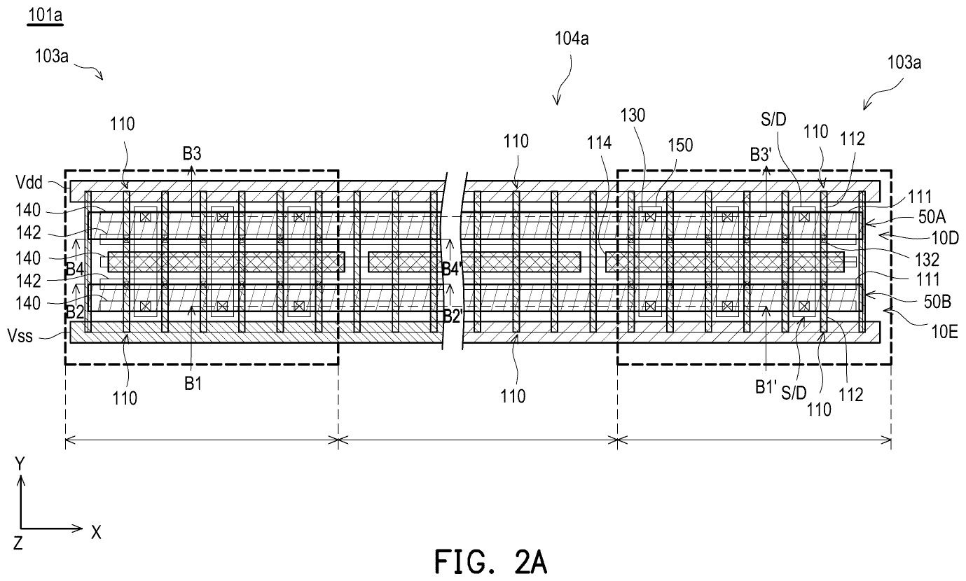

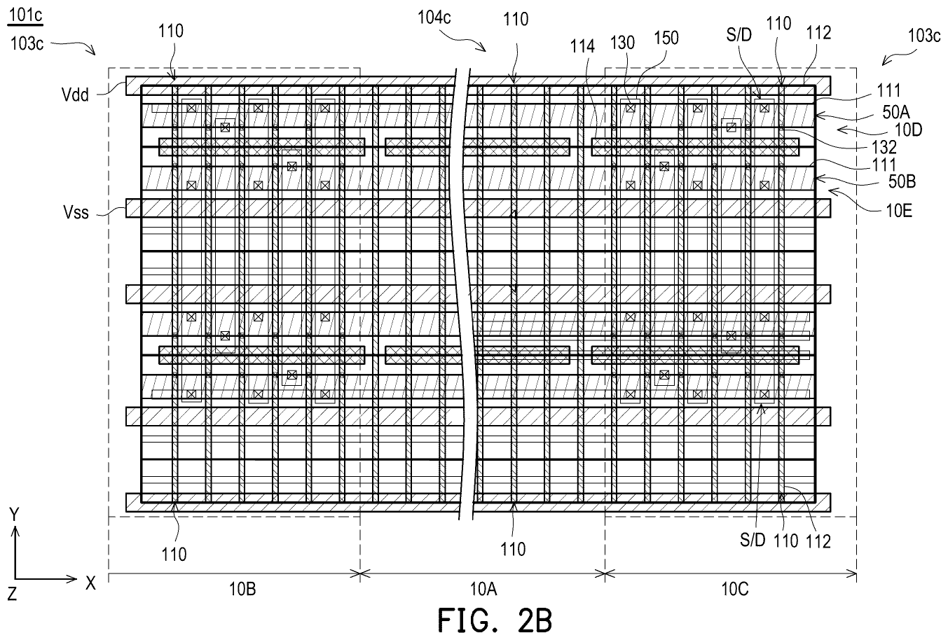

Therefore, the present disclosure in various embodiments provides a method to enhance the performance of die-to-die I/O circuits in 3DIC. The I/O circuit can integrate a buffer circuit with an ESD protection circuit. A driving strength of the buffer circuit (e.g., 16 PMOS and 16 NMOS transistors) can be divided into two sub-buffer regions (e.g., buffer circuit regions 10B and 10C shown in FIG. 2A), each wielding half of the total driving strength (e.g., 8 PMOS and 8 NMOS). Specifically, for output stage, the transistors in the sub-buffer regions connect their source/drain regions to those in a ESD protection circuit region via a horizontal metal line. The two sub-buffer regions can be positioned on opposite sides of the ESD protection circuit region (e.g., ESD protection circuit region 10A shown in FIG. 2A). This arrangement can split and shorten the horizontal current path, reducing the length of the current path to between 50% and 75% of its original length, leading to a decrease in output capacitance loading and boosts electromigration resilience.

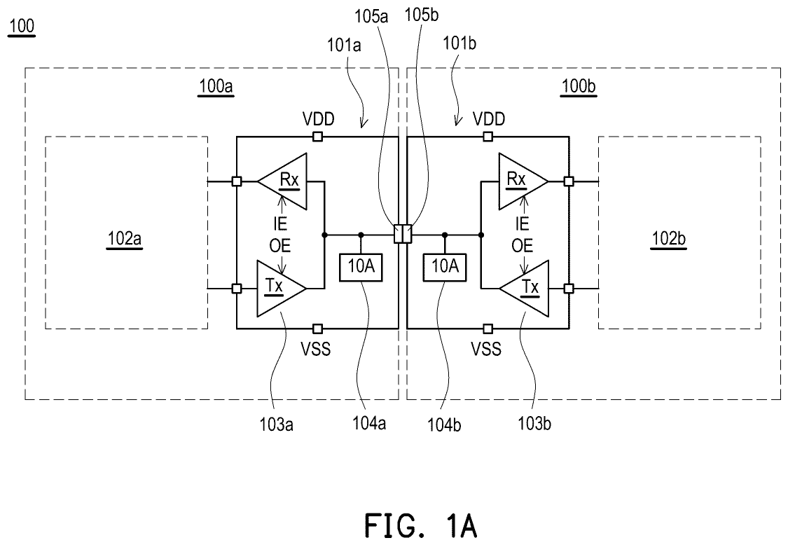

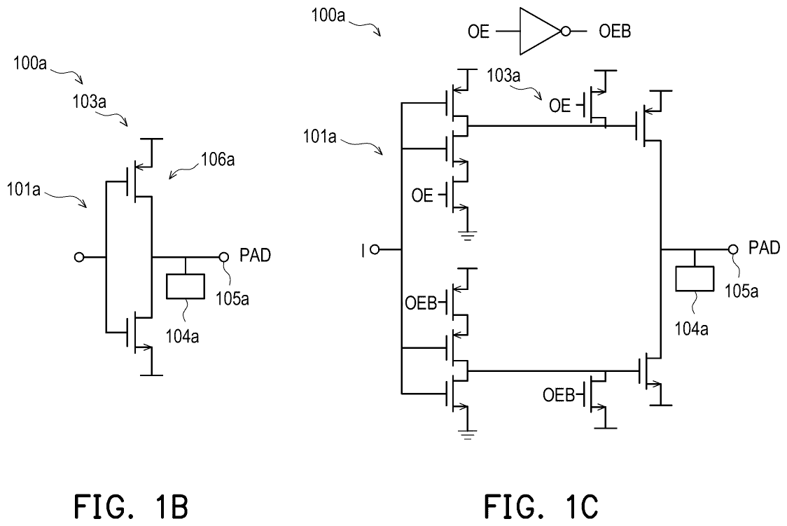

Reference is made to FIGS. 1A-1C. FIG. 1A illustrates a schematic block diagram of an IC device 100 in accordance with some embodiments of the present disclosure. FIG. 1B illustrates a schematic plan circuit diagram of a buffer circuit 103a combined with an electrostatic discharge (ESD) protection circuit 104a within the IC device 100 in accordance with some embodiments of the present disclosure. FIG. 1C illustrates a schematic plan circuit diagram of a buffer circuit 103b combined with an ESD protection circuit 104b within the IC device 100 in accordance with some embodiments of the present disclosure.

As shown in FIG. 1A, the IC device 100 comprises a first die 100a and a second die 100b electrically and/or physically coupled to each other. In some embodiments, the first die 100a and the second die 100b are stacked over each other, and are physically bonded and electrically coupled to each other in a 3DIC through pads 105a and 105b thereof. In some embodiments, the first die 100a and the second die 100b are arranged side-by-side on and physically bonded to a further substrate or die (not shown), and are electrically coupled to each other through the further substrate or die. In some embodiments, the IC device 100 comprises more than two dies electrically and/or physically coupled to each other. In some embodiments, the IC device 100 has one die, e.g., the first die 100a, whereas the other die, e.g., the second die 100b, is omitted. In the example configuration in FIG. 1A, the second die 100b is configured similarly to the first die 100a. The first die 100a is described in detail herein, and a detailed description of the second die 100b is omitted. The first die 100a can include one or more functional circuits and one or more input/output (I/O) circuits electrically coupled to the one or more functional circuits. In FIG. 1A, a representative I/O circuit 101a and a representative functional circuit 102a of the first die 100a are illustrated. In some embodiment, the I/O circuit 101b and the functional circuit 102b of the second die 100b can correspond to the I/O circuit 101a and the functional circuit 102a of the first die 100a.

In some embodiment, the functional circuit 102a can be configured to perform an intended function, e.g., data processing or data storage, of the IC device 100. Examples of one or more circuits, logics, or cells included in the functional circuit 102a include, but are not limited to, AND, OR, NAND, NOR, XOR, INV, OR-AND-Invert (OAI), MUX, Flip-flop, BUFF, Latch, delay, clock, memory, or the like. The circuits, logics, or cells included in the functional circuit 102a include functional transistors or core transistors which are to be protected from the antenna effect during the manufacture of the IC device 100. Examples of transistors in the functional circuit 102a, as well as in the other circuits described herein, include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

In some embodiment, the I/O circuit 101a can be electrically coupled to the functional circuit 102a, and can be configured as an interface between the functional circuit 102a on the first die 100a and external circuitry outside the first die 100a. In the example configuration in FIG. 1A, the I/O circuit 101a can include the buffer circuit 103a and the ESD protection circuit 104a, in which the buffer circuit 103a may include a receiving circuit Rx (also referred to as “input circuit”) and a transferring circuit Tx (also referred to as “output circuit”), and all of which are electrically coupled to a pad 105a which can be an I/O pin. In some embodiment, the buffer circuit 103b, the ESD protection circuit 104b, and the pad 105b of the second die 100b can correspond to the buffer circuit 103a, the ESD protection circuit 104a, and the pad 105a of the first die 100a. In some embodiment, the pad 105a can be interchangeable referred to as a metal pad, a pad pin, or a die-to-die pad.

The buffer circuit 103a can be used to strengthen and stabilize the signals being transmitted in and out of the die 100a. In some embodiments, the buffer circuit 103a can condition the signal, such as inverting it (e.g., inverter buffer shown in FIG. 1B) or providing multiple states (e.g., tri-state buffer shown in FIG. 1C). In some embodiments, the buffer circuit 103a can provide isolation between circuits, protecting a circuit from the potentially harmful effects of the connected circuit. In some embodiments, the buffer circuit 103a can be changeably referred to as an ESD victim.

In some embodiment, the receiving circuit Rx in the buffer circuit 103a can be configured to send a signal on the pad 105a to the functional circuit 102a. The receiving circuit Rx can be configured to receive an input enable signal IE. The receiving circuit Rx can be enabled to send the signal on the pad 105a to the functional circuit 102a in response to a logic state of the input enable signal IE, and can be disabled from sending the signal on the pad 105a to the functional circuit 102a in response to a different logic state of the input enable signal IE. The transferring circuit Tx in the buffer circuit 103a can be configured to send a signal output by the functional circuit 102a to the pad 105a. The transferring circuit Tx can be configured to receive an output enable signal OE. The transferring circuit Tx can be enabled to send the signal output by the functional circuit 102a to the pad 105a in response to a logic state of the output enable signal OE, and can be disabled from sending the signal output by the functional circuit 102a to the pad 105a in response to a different logic state of the output enable signal OE. Examples of the signal(s) input from or output to the pad 105a include, but are not limited to, data, power, clock, control, or the like. Examples of one or more circuits in at least one of the receiving circuit Rx or transferring circuit Tx include, but are not limited to, a buffer, a latch, a level shifter, or the like.

In some embodiment, the ESD protection circuit 104a can be configured to protect the other circuits, including the functional circuit 102a, that are electrically coupled to the pad 105a from ESD events occurring on the pad 105a during operation or handling of the first die 100a or IC device 100. By way of example and not limitation, the ESD protection circuit 104a can employ components like diodes to clamp the voltage to a safe level when an ESD event occurs, preventing the voltage spike from reaching and damaging the sensitive parts in the die 100a. In some embodiment, the ESD protection circuit 104a can serves to divert the excess current away from sensitive circuit components. Examples of the ESD protection circuit 104a include, but are not limited to, a diode, a grounded-gate NMOS (ggNMOS), a silicon-controlled rectifier (SCR), or the like. In some embodiments, transistors in the ESD protection circuit 104a can be larger than and/or have a different configuration from the functional transistors or core transistors of the functional circuit 102a to be able to sustain and handle high voltages and/or current of ESD events.

In some embodiment, the first die 100a is electrically coupled to the second die 100b at one or more die-to-die interconnects. In FIG. 1A, a representative die-to-die interconnect is illustrated, and is electrically coupled to the pad 105a of the first die 100a and to a corresponding pad 105b of the second die 100b. As a result, the pad 105a of the first die 100a is electrically coupled to the corresponding pad 105b of the second die 100b through the die-to-die interconnect. In some embodiments, the die-to-die interconnect can be a through-silicon via (TSV) in one or more dies of the IC device 100.

Reference is made to FIGS. 1B and 1C. FIGS. 1B and 1C illustrate different configurations of the I/O circuit 101a within the die 100a, focusing on variations in the buffer circuit 103a. As shown in FIG. 1B, the buffer circuit 103a can include an inverter 106a. The inverter 106a can be a fundamental digital logic circuit that flips the input signal's state; if the input is high (e.g., 1), the output is low (e.g., 0), and vice versa. The inverter 106a in the buffer circuit 103a can include of at least one pair of transistors (e.g., an NMOS transistor and a PMOS transistor). The ESD protection circuit 104a can be used to safeguard the inverter 106a and other components from electrostatic discharge damage. The pad 105a can serve as the interface for the buffer circuit's output. In this case, the output of the inverter 106a can be routed to pad 105a, providing a signal inversion for external communication or further internal processing within the die 100a.

As shown in FIG. 1C, the buffer circuit 103a can incorporate a tri-state buffer. The tri-state buffer can be in one of three states: high, low, or high-impedance, allowing for further control and interaction with bus systems or shared signal lines. The transistor arrangement in the tri-state buffer may include additional transistors controlled by enable signals to achieve the high-impedance state. The signals (e.g., output enable OE and output enable bar OEB) can control the state of the tri-state buffer. The output enable OE might activate the buffer (allowing normal operation), while the output enable bar OEB could put the buffer into a high-impedance state, disconnecting it from the output pad 105a. The ESD protection circuit 104a can be used to safeguard the tri-state buffer and other components from electrostatic discharge damage. The pad 105a can serve as the interface for the tri-state buffer's output. In this case, depending on the state controlled by the output enable OE and the output enable bar OEB, the pad 105a may receive either a high or low signal, or be electrically disconnected from the buffer circuit 103a.

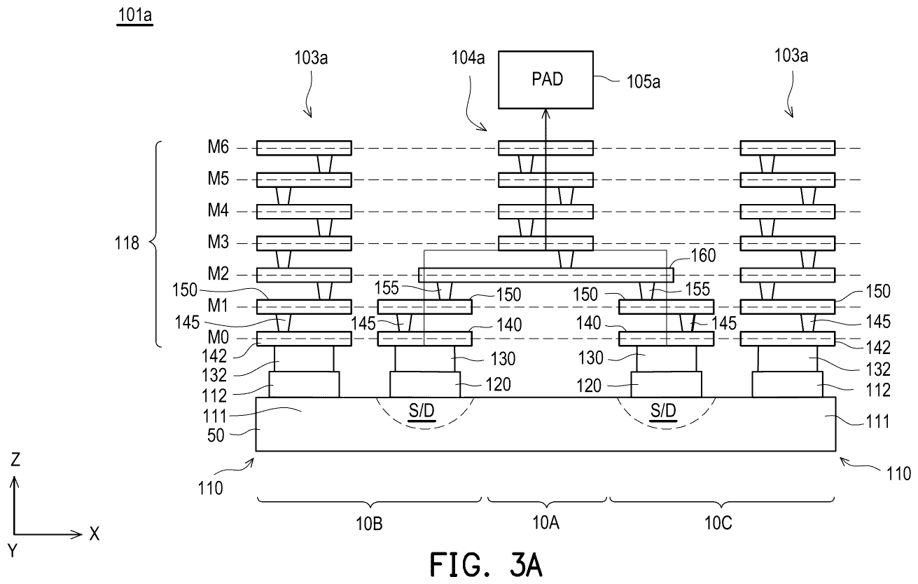

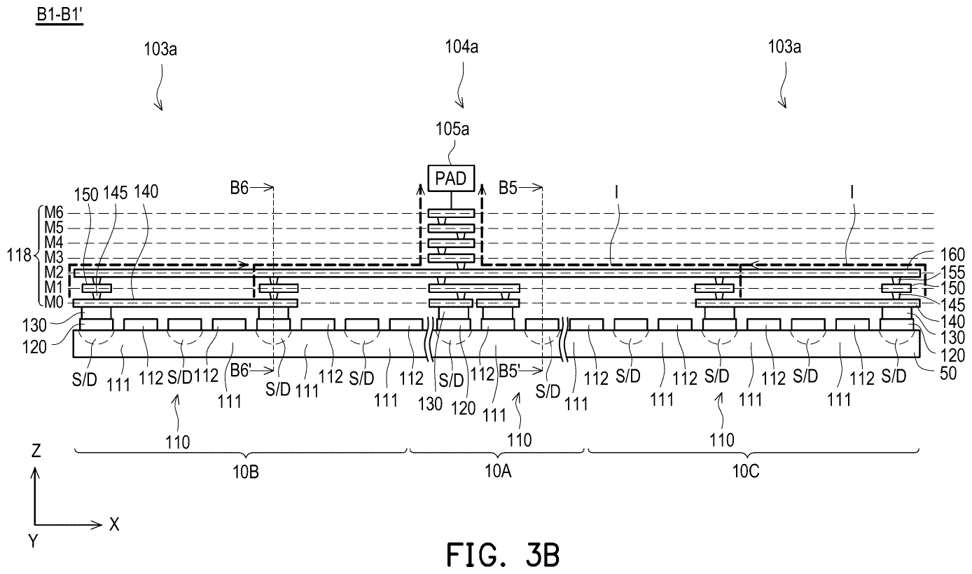

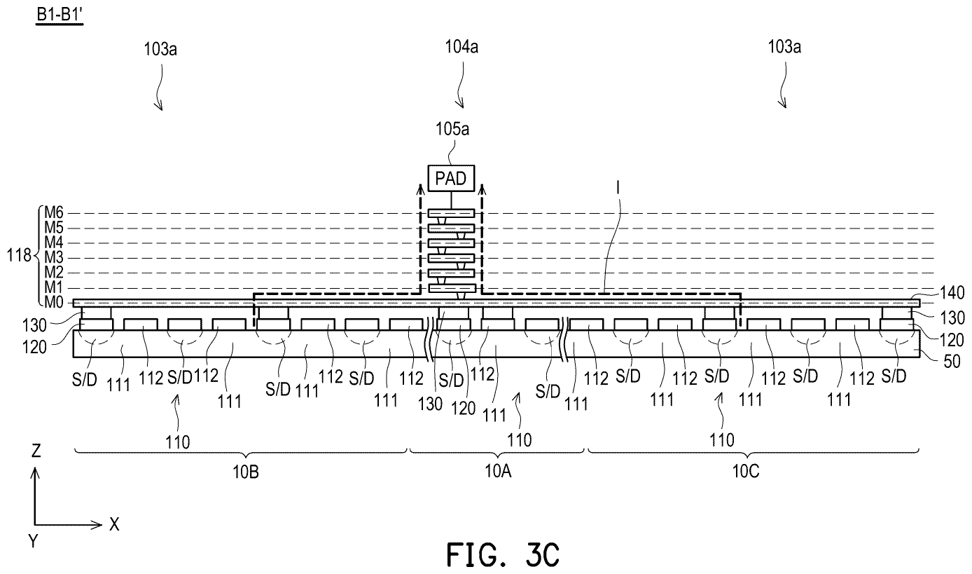

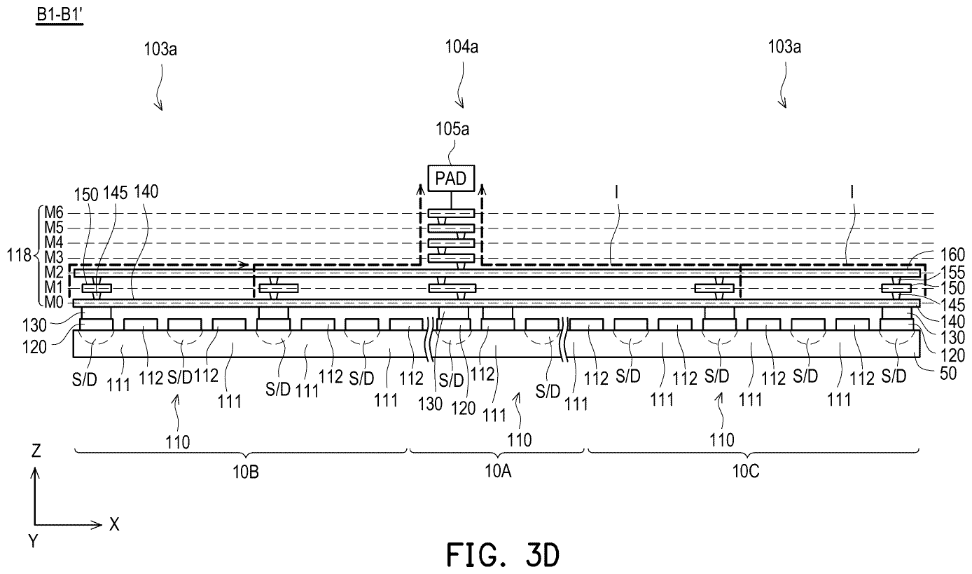

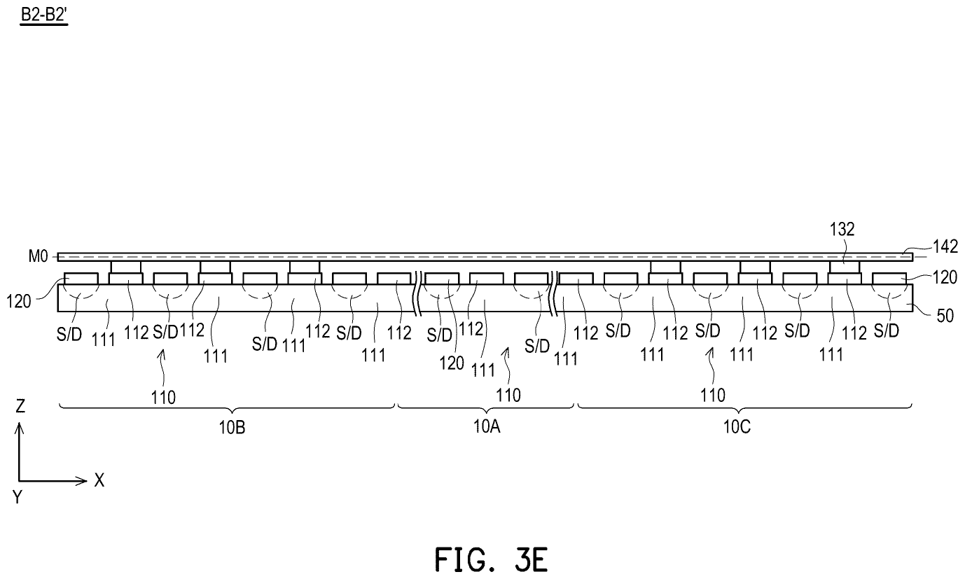

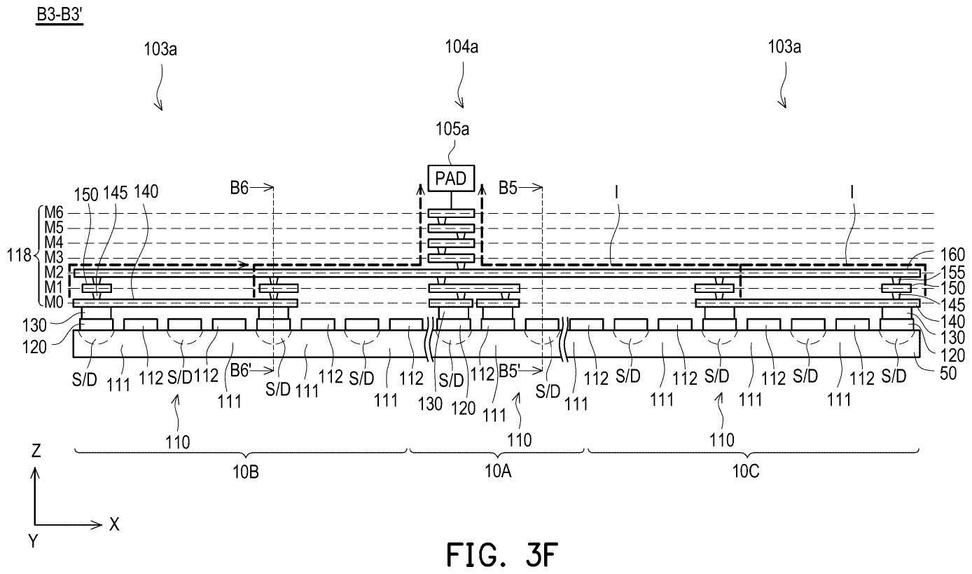

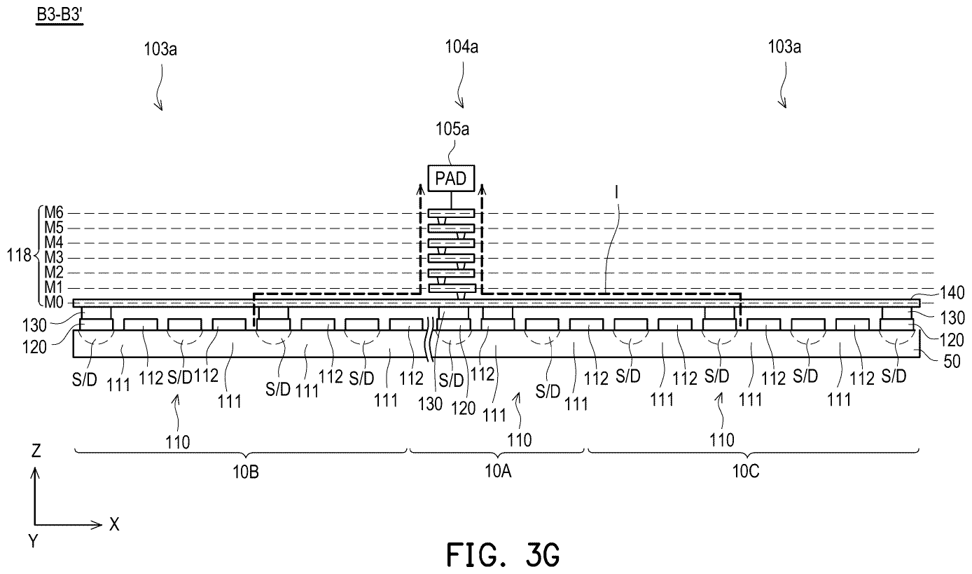

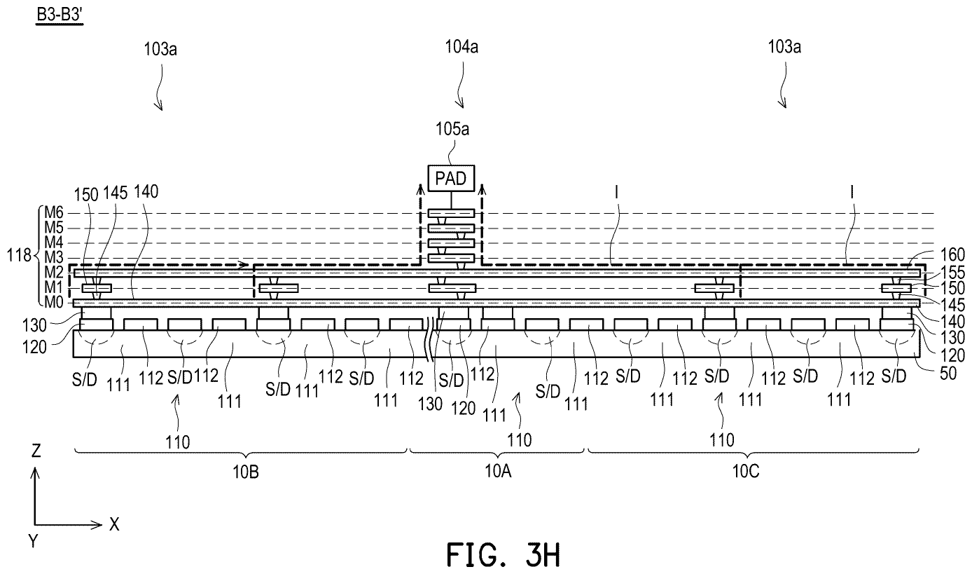

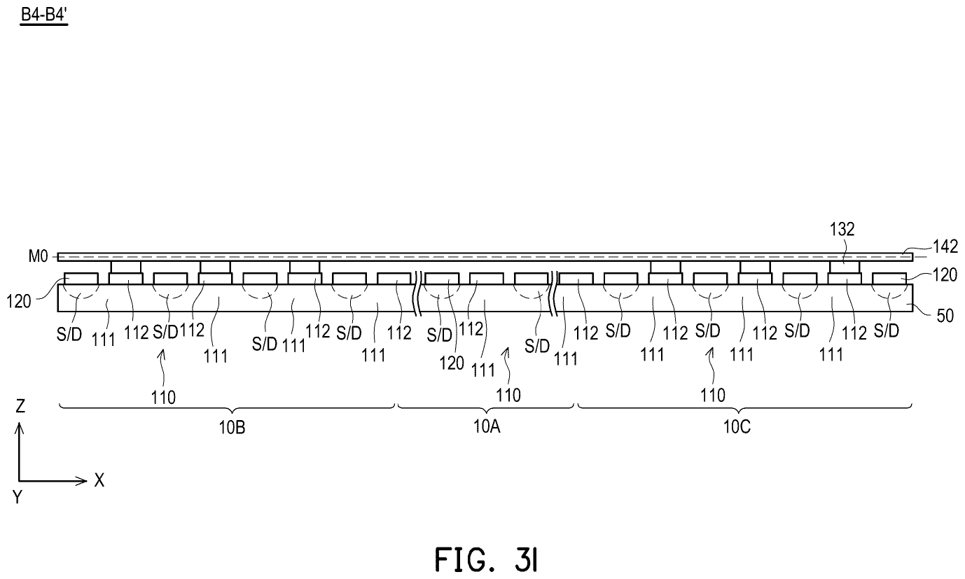

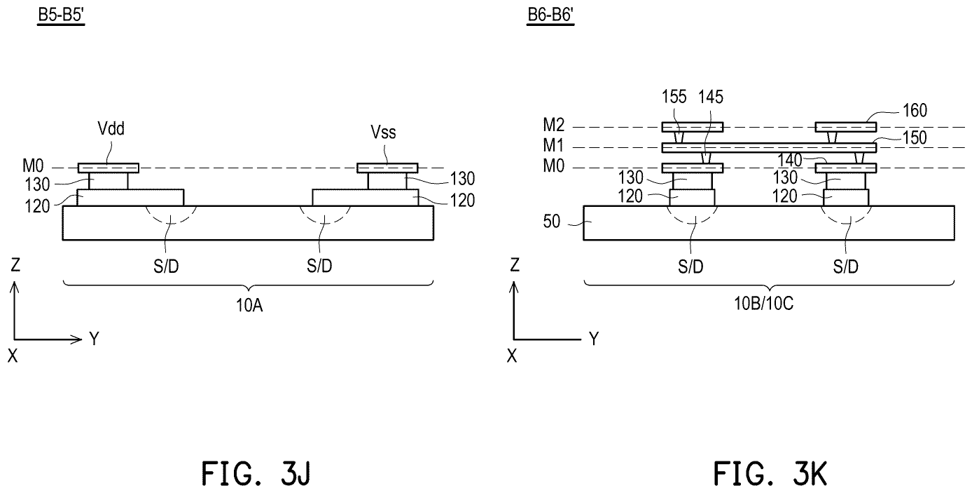

Reference is made to FIGS. 2A and 3A-3K. FIG. 2A illustrates a top view layout pattern of the I/O circuit 101a including the buffer circuit 103a with the ESD protection circuit 104a in accordance with some embodiments of the present disclosure. FIG. 3A illustrates a schematic cross-sectional view of the I/O circuit 101a including a buffer circuit 103a with an ESD protection circuit 104a in accordance with some embodiments of the present disclosure. FIG. 3B illustrate cross-sectional views of the I/O circuit 101a obtained from a reference cross-section Bl-Bl′ in FIG. 2A in accordance with some embodiments of the present disclosure. FIGS. 3C and 3D illustrate cross-sectional views of IC structures corresponding to FIG. 3B in accordance with some embodiments of the present disclosure. FIG. 3E illustrates a cross-sectional view of the I/O circuit 101a obtained from a reference cross-section B2-B2′ in FIG. 2A in accordance with some embodiments of the present disclosure. FIG. 3F illustrates a cross-sectional view of the I/O circuit 101a obtained from a reference cross-section B3-B3′ in FIG. 2A in accordance with some embodiments of the present disclosure. FIGS. 3G and 3H illustrate cross-sectional views of IC structures corresponding to FIG. 3F in accordance with some embodiments of the present disclosure. FIG. 3I illustrates a cross-sectional view of the I/O circuit 101a obtained from a reference cross-section B4-B4′ in FIG. 2A in accordance with some embodiments of the present disclosure. FIG. 3J illustrates a cross-sectional view of the I/O circuit 101a obtained from a reference cross-section B5-B5′ in FIGS. 3B and 3F in accordance with some embodiments of the present disclosure. FIG. 3K illustrates a cross-sectional view of the I/O circuit 101a obtained from a reference cross-section B6-B6′ in FIGS. 3B and 3F in accordance with some embodiments of the present disclosure.

As shown in FIGS. 2A and 3A, the I/O circuit 101a can have an ESD protection circuit region 10A, a first buffer circuit region 10B, and a second buffer circuit region 10C arranged over a substrate 50 (see FIG. 3A). The ESD protection circuit region 10A can be situated (or localized) between the first and second buffer circuit regions 10B and 10C. It should be noted that the configuration of the ESD protection circuit region 10A and the first and second buffer circuit regions 10B and 10C in the I/O circuit 101a are used as an illustration, and not to limit the disclosure. In other words, the transistor in the ESD protection circuit region 10A can interpose between the transistor 110 in the first buffer circuit region 10B and the transistor 110 in the second buffer circuit region 10C (see FIG. 3B). By way of example but not limiting the present disclosure, the first and second buffer circuit regions 10B and 10C each may have at least one inverter.

The pad 105a (see FIG. 3A) first connects to the ESD protection circuit 104a on the ESD protection circuit region 10A before routing to the buffer circuit 103a on the first and second buffer circuit region 10B/10C. This means that for buffer circuit 103a, the initial connection can be with the ESD protection circuit 103a. This connection order can lead to a horizontal current path (e.g. metal line 160 shown in FIG. 3A) between the pad 105a and the transmitter in the buffer circuit 103a on the first and second buffer circuit region 10B/10C. The pad 105a electrically couples to the ESD protection circuit 103a (e.g., source/drain region S/D of transistor 110 within the ESD protection circuit region 10A shown in FIG. 3B) through various interconnect, such as hybrid bump, microbump (mbump), or through-silicon via (TSV). In FIG. 3A, for the output stage, the source/drain region S/D of the transistor 110 in the ESD protection circuit region 10A is electrically coupled to the source/drain region S/D of another transistor 110 (which acts as a transmitter) in the buffer region 10B/10C through the horizontal metal line 160. On the contrary, for the input stage, the source/drain region S/D of the transistor 110 in the ESD protection circuit region 10A is electrically coupled to a gate structure of a different transistor 110 (serving as a receiver) in the buffer region 10B/10C.

In some embodiments, the time rise and fall of signals in the circuit should be less than one-sixth of the operating period. This requirement may indicate that the operating speed of the die-to-die I/O circuit can be limited by electromigration (EM) issues. In some embodiments, the speed of the die-to-die I/O circuit may be limited by electromigration in the horizontal trace (e.g. metal line 160 shown in FIG. 3A), in which the horizontal trace may have potential current crowding.

The buffer circuit 103a can be built in a semiconductor structure that is divided into two sub-buffer regions (e.g., first and second buffer circuit regions 10B and 10C). By placing the first and second buffer circuit regions 10B and 10C on opposite sides of the ESD protection circuit region 10A, the horizontal current path in the metal line (e.g. metal line 160 shown in FIG. 3A) is split and shortened. This reduction in the length of the current path (to about 50% to 75% of its original length) can alleviate issues related to current crowding and electromigration. In some embodiments, shorter horizontal metal lines can lead to lower output capacitance loading. This can result in an electromigration boost, allowing for higher speed and driving capability for heavy loads, which in turn improves electromigration/IR-drop (EMIR) issues without degrading the rise/fall time of signals. Therefore, the I/O circuit 101a can reduce the stress caused by electromigration by greater than about 50%, such as about 50%, 55%, 60%, 65%, 70%, 75%, 80%, 85%, 90%, and 95%. By reducing stress, the I/O circuit 101a can extend the lifespan of the circuit. Additionally, the I/O circuit 101a can achieve an electromigration relaxation greater than about 1.7 times, indicating that the circuits are substantially more resistant to the damaging effects of electron. Moreover, the I/O circuit 101a can offer a speed boost greater than about 1.15 times.

Furthermore, the total driving strength of the buffer circuit 103a, represented by a certain number of PMOS and NMOS transistors (e.g., 12 PMOS transistors and 12 NMOS transistors), is divided into two sub-buffer regions. Each sub-buffer region then possesses a portion of the total driving strength (e.g., 6 PMOS transistors and 6 NMOS transistors as shown in FIG. 2A) and has its own set of transistors, and the first and second buffer circuit regions 10B and 10C are located on opposite sides of the ESD protection circuit region 10A.

Specifically, as shown in FIGS. 2A and 3A, the I/O circuit 101a may include transistors 110 within a first conductivity type device region 10D (see FIG. 2A) and a second conductivity type device region 10E (see FIG. 2A) over the substrate 50 (see FIG. 3A). In some embodiments, the transistors 110 in the first conductivity type device region 10D may be PMOSFET transistors with silicon channel regions, and the transistors 110 in the second conductivity type device region 10E may be NMOSFET transistors with silicon channel regions. In some embodiments, the transistors 110 may be GAA FETs, and thus the silicon channel regions of the NMOS and PMOS transistors can be formed by semiconductor sheets (not shown). In some embodiments, a second conductivity type well 50A (see FIG. 2A) and a first conductivity type well 50B (see FIG. 2A) can be formed in the substrate 50. By way of example but not limiting the present disclosure, the second conductivity type well 50A may be a n-well, and the first conductivity type well 50B may be p-well.

The transistors 110 can include channel regions 111 formed over the first and second conductivity type wells 50A and 50B (see FIG. 2A). The transistors 110 can further include gate structures 112 within the ESD protection circuit region 10A and the buffer circuit regions 10B and 10C and extending in the Y-direction. In some embodiment, the gate structure 112 can be interchangeable referred to as a functional gate, a gate strip, a gate pattern, or a gate layer. The transistors 110 can further include source/drain regions S/D over the channel region 111 and at opposite sides of the gate structure 112. In some embodiments, a dopant in the source/drain region S/D of the first conductivity type device region 10D (see FIG. 2A) has an opposite conductivity type to a dopant in the source/drain region S/D of the second conductivity type device region 10E (see FIG. 2A). For example, the source/drain region S/D of the first conductivity type device region 10D may have an p-type dopant, and the source/drain region S/D of the second conductivity type device region 10E may have an n-type dopant.

In FIG. 2A, the I/O circuit 101a can include cut polysilicon (CPO) structure 114, which can be used to separate adjacent gate structures 112. The cut polysilicon structure 114 can be used for isolating individual transistors 110 or transistor groups within the I/O circuit 101a. In some embodiments, the cut polysilicon structure 114 can be made of a dielectric material and can be changeably referred to as an isolation structure, an isolation strip, or an isolation line pattern.

In some embodiments, a source/drain region S/D can be electrically coupled to an overlying metal line in a frontside interconnect structure 118 (see FIG. 3A) through a source/drain contact 120 (see FIG. 3A) and a source/drain via 130 (see FIG. 3A). The gate structure 112 can be electrically coupled to another overlying level metal line in the frontside interconnect structure 118 through a gate via 132. The frontside interconnect structure 118 can be formed over the transistors 110 and may include, for example, seven metallization layers, labeled as M0, M1, M2, M3, M4, M5, and M6, with a plurality of layers of metallization vias connected therebetween. Other embodiments may contain more or fewer metallization layers and corresponding more or fewer number of vias. The metal line illustrated here just for an example, and the metal line may be otherwise oriented (rotated 90 degrees or at other orientations). The frontside interconnect structure 118 further comprises various interlayer dielectric layers (not shown) in which the metallization layers and the vias are embedded.

In some embodiments, metal lines disposed at the M0 level (see FIG. 3A) over the substrate 50 may include a power supply voltage line Vss (see FIG. 2A), a power supply voltage line Vdd (see FIG. 2A), a metal line 140 (see FIGS. 3A, 3B and 3F), and a metal line 142 (see FIGS. 3A, 3E and 3I). The metal lines disposed at the M0 level may have lengthwise directions in parallel to the X-direction. In some embodiments, the buffer circuit 103a can be powered through the power supply voltage line Vdd, and the power supply voltage lines Vss can be provided with an electrical ground. The power supply voltage lines Vdd and Vss can be electrically connected to source terminals of the first and second buffer circuit regions 10B and 10C (see FIG. 2A) through the source/drain contacts 120 (see FIG. 3A) and the source/drain vias 130. The metal lines 140 and 142 can be laterally between the power supply voltage lines Vdd and Vss. The metal line 140 can be electrically connected to drain terminals of the source/drain regions S/D in the first and second buffer circuit regions 10B and 10C (see FIGS. 2A, 3A, and 3F) through the source/drain contacts 120 and the source/drain vias 130. The metal line 142 can be electrically connected to the gate structure 112 in the first and second buffer circuit regions 10B and 10C through the gate via 132 (see FIGS. 2A, 3E, and 3I). In some embodiments, the metal line 142 can extend beyond opposite boundaries of the ESD protection circuit region 10A and to reach the divided first and second buffer circuit regions 10B and 10C. In some embodiments, the metal line 142 can extend across the ESD protection circuit region 10A and the first and second buffer circuit regions 10B and 10C. In some embodiments, a length of the metal line 142 can be longer than a length of the metal line 140.

In some embodiments, metal lines disposed at the Ml level over the M1 level may include metal lines 150 (see FIGS. 3A, 3B, and 3F). The metal lines disposed at the Ml level may have lengthwise directions in parallel to the Y-direction. The metal lines 150 can be electrically connected to the metal lines 140/142 (see FIGS. 3A, 3B and 3F) in the first and second conductivity type device regions 10D and 10E (see FIG. 2A) through underlying vias 145.

In some embodiments, metal lines disposed at the M2 level over the M1 level may include metal lines 160 (see FIGS. 3A, 3B and 3F). The metal lines disposed at the M2 level may have lengthwise directions in parallel to the X-direction. The metal lines 160 can be electrically connected to the metal lines 150 (see FIGS. 3A, 3B, and 3F) through underlying vias 155. In other words, as shown in FIGS. 3B and 3F, the source/drain region S/D of the transistor 110 in the buffer circuit 103a can be electrically connected to the source/drain region S/D of another transistor 110 in the ESD protection circuit 103a through the horizontal metal line 160 (i.e., horizontal current path). In some embodiments, the speed of the die-to-die I/O circuit may be limited by electromigration in the metal line 160. The metal line 160 can extend beyond opposite boundaries of the ESD protection circuit region 10A and to reach the divided first and second buffer circuit regions 10B and 10C, which in turn reduces in the length of the current path, such that current crowding and electromigration issues can be alleviated.

In some embodiments, the metal line 160 can extend across the ESD protection circuit region 10A and the first and second buffer circuit regions 10B and 10C, such that the metal line 160 can extend across the gate structures 112 in the ESD protection circuit region 10A and the first and second buffer circuit regions 10B and 10C. The metal line 160 can extend horizontally from above the transistor 110 in the first buffer circuit region 10B, across the transistor 110 in the ESD protection circuit region 10A, and to above the transistor 110 in the second buffer circuit region 10C. In some embodiments, the metal line 160 has a length greater than underlying metal line 140 connected to the source/drain vias 130. In some embodiments, the metal line can be interchangeable referred to as a trace and a path. In some embodiments, materials of the lines Vss, Vdd, 140, 142, 150, and 160, the contact 120, and/or the vias 130 and 132 may be made of Cu, Co, Ru, Pt, Al, W, Ti, TaN, TiN, or any combinations thereof.

FIGS. 3B-3D and 3F-3H illustrate various methods of connecting the buffer circuit 103a to the ESD protection circuit 104a. These methods utilize different metal line levels (e.g., M0 level, M2 level) within the IC structure to establish this connection. This flexibility can allow for optimizing the signal transmission paths (e.g., marked with dotted lines in FIGS. 3B-3D and 3F-3H).

In FIGS. 3C and 3G, the connection between the buffer circuit 103a and the ESD protection circuit 104a can be established using the metal line 140 at the M0 level, which provides a path for signal transmission from the buffer circuit 103a to the ESD protection circuit 104a, simplifying the overall layout. The dotted line in FIGS. 3C and 3G illustrate the flow of a signal I through the metal line 140. In FIGS. 3D and 3H, the connection between the buffer circuit 103a and the ESD protection circuit 104a can be established using both the metal line 140 at the M0 level and the metal line 160 at the M2 level, which provides a flexibility in routing and reduces electromigration or enhancing signal integrity. The dotted line in FIGS. 3D and 3H illustrate the flow of the signal I through the metal lines 140 and 160. In FIGS. 3B and 3F, the connection between the buffer circuit 103a and the ESD protection circuit 104a can be established using the metal line 160 at the M2 level. In some embodiments, this higher-level metal line (e.g. M4 level or M6 level) can be used for longer connections or to navigate around other components in the IC structure. The dotted line in FIGS. 3B and 3F illustrate the flow of the signal I through the metal lines 140 and 160.

FIG. 2B illustrates a top view layout pattern of an I/O circuit 101c including a buffer circuit 103c with an ESD protection circuit 104c in accordance with some embodiments of the present disclosure. The buffer circuit 103c and the ESD protection circuit 104c can correspond to the buffer circuits 103a and the ESD protection circuit 104a of the I/O circuit 101c as shown in FIGS. 2A and 3A-3K. The difference between the I/O circuit 101a shown in FIGS. 2A and 3A-3K and this embodiment is that, the first and second buffer circuit regions 10B and 10C in the I/O circuit 101c have an increased number of transistors 110 arranged along the opposite boundaries of the ESD protection circuit region 10A (e.g., along the Y-direction), such that the overall driving strength of the buffer circuits 103c can be boosted. The additional transistors in regions 10B and 10C enhance the ability of the buffer circuit to drive signals with higher power and efficiency, making the circuit more robust in handling larger loads or faster signal transmission. Furthermore, the placement of additional transistors 110 in the buffer regions 10B and 10C can allow for a more direct and shorter horizontal current path between the buffer circuit 103c and the ESD protection circuit 104c, which in turn minimizes the distance the signal needs to travel and reduces risk of electromigration. The configuration of I/O circuit 101c remains similar to that of I/O circuit 101a. It maintains the same fundamental structure with ESD protection circuit region 10A localized between the first and second buffer circuit regions 10B and 10C.

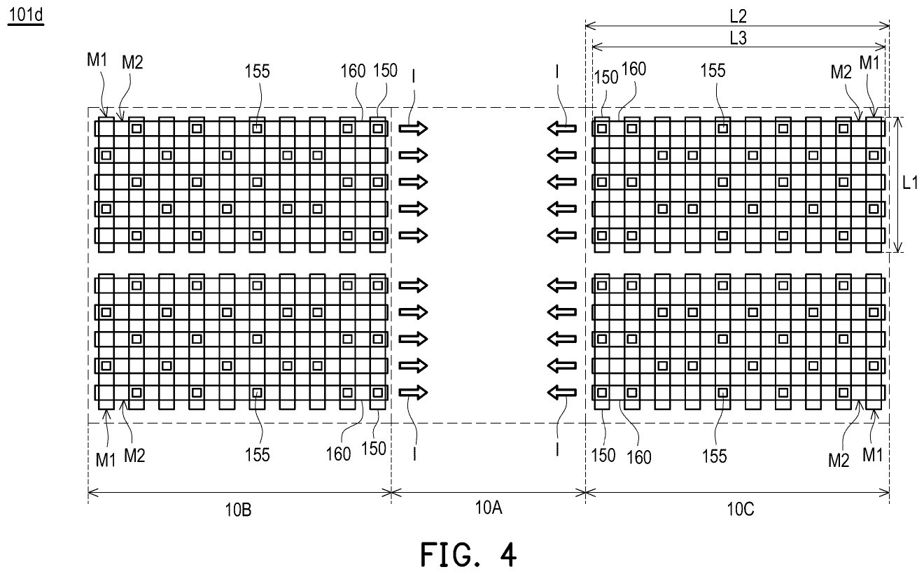

Reference is made to FIG. 4. FIG. 4 illustrates a top view layout pattern of the I/O circuit 101d including a buffer circuit and an ESD protection circuit (not shown) with the metal lines 150 and 160 at the M1 level and M2 level and via 155 sandwiched between the metal lines 150 and 160 in accordance with some embodiments of the present disclosure. The buffer circuit and the ESD protection circuit can correspond to the buffer circuits 103c and the ESD protection circuit 104c of the I/O circuit 101c as shown in FIG. 2B. As shown in FIG. 4, the metal line 150 at the M1 level can be split (or cut) to create a forced split in the current path, which in turn distributes the current flow more evenly across the circuit, thereby lowering the risk of electromigration. In some embodiment, the metal line 150 at the M1 level may have a length L1 less than a dimension L2 of the buffer circuit region 10B/10C in a lengthwise direction (or Y-direction) of the metal line 160. In some embodiment, the length L1 of the metal line 150 may be less than a length L3 of the metal line 160.

Additionally, the layout can ensure a balanced or uniform configuration of the underlying vias 155 for each metal line 160 at the M2 level. This means that the number of vias 155 connecting to each metal line 160 is kept consistent across the circuit. In some embodiment, to maintain uniformity, the difference in the number of vias 155 below two adjacent metal lines 160 can be controlled to not exceed a certain threshold, for example, not greater than 5, such as 4, 3, 2, 1, ensuring that no single metal line 160 is disproportionately burdened with current, which could lead to increased EM stress. In some embodiments, the difference in the number of vias 155 below two adjacent metal lines 160 can be controlled to be not greater than 3. The combination of splitting the metal line 150 at the M1 level and balancing the via number at the M2 level can lead to a more evenly distributed current flow. This distribution can reduce localized points of high current density, resulting in greater than about 15% reduction in electromigration stress. In some embodiment, the number of vias 155 of a first group on a first one of the metal lines 160 can be substantially the same as the number of vias 155 of a first group on a second one of the metal lines 160.

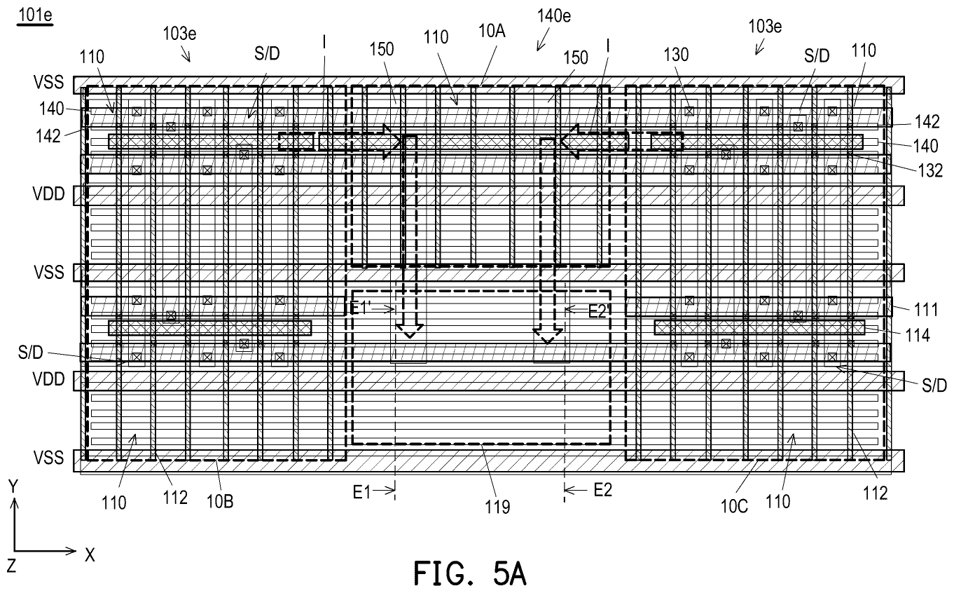

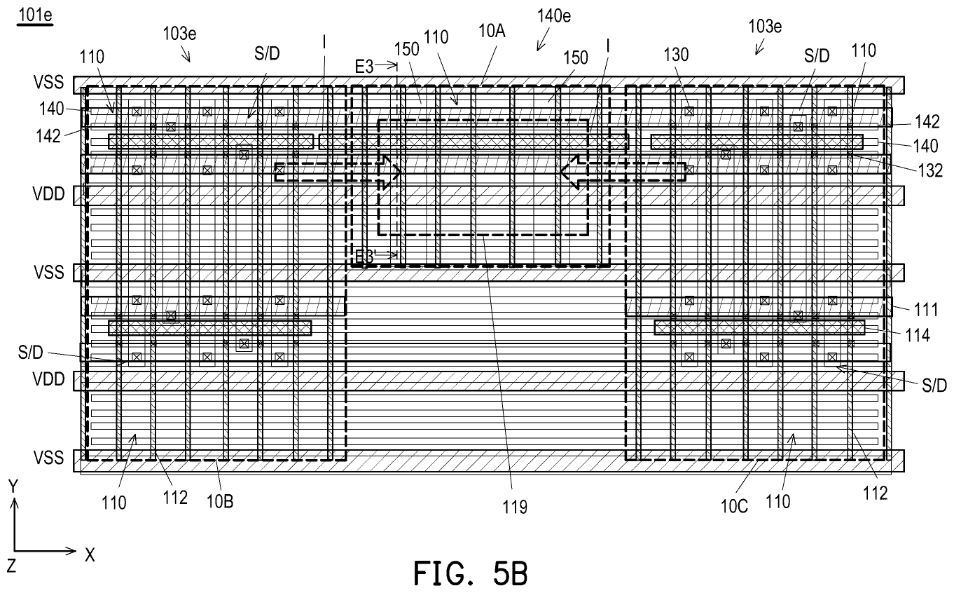

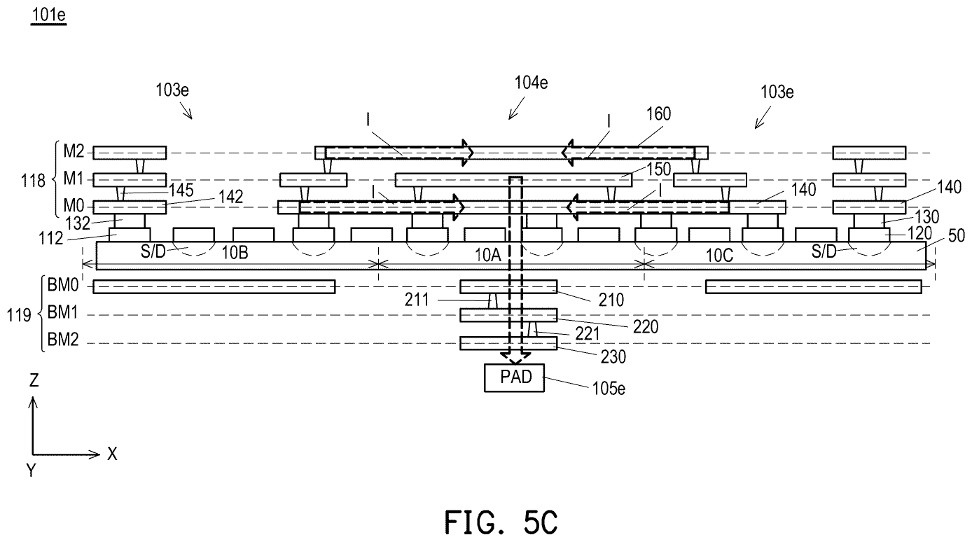

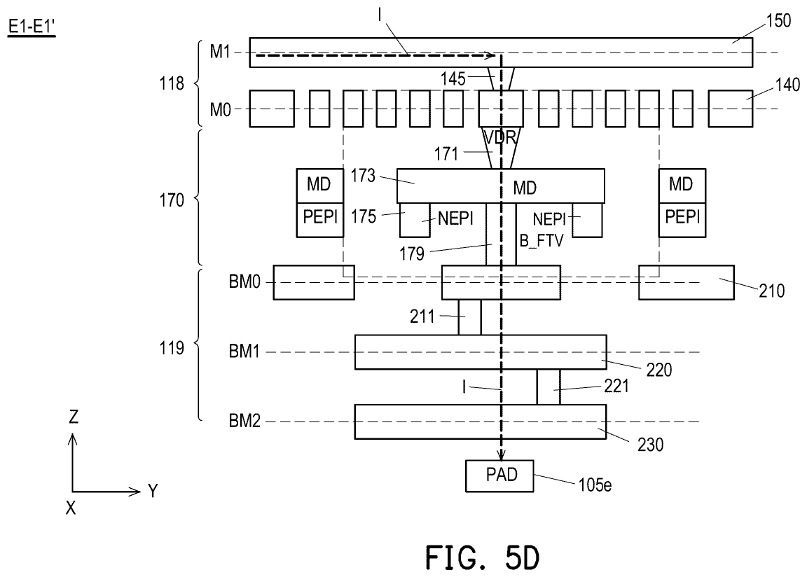

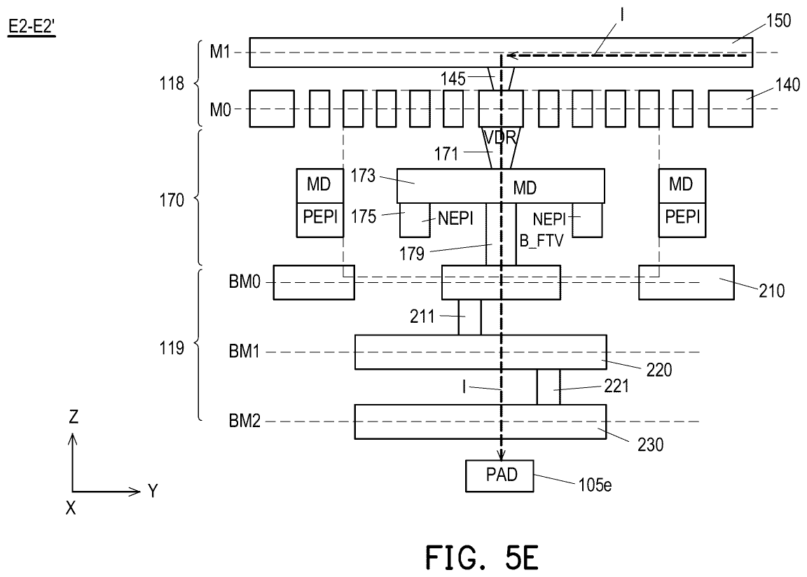

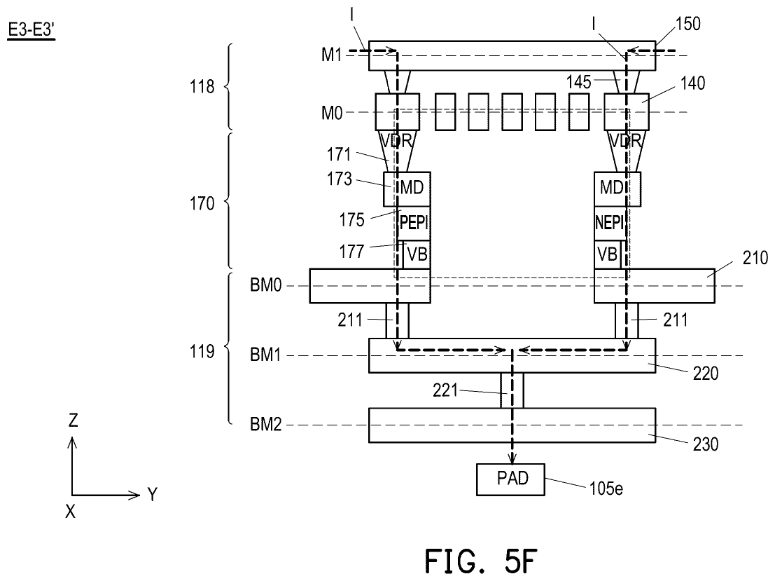

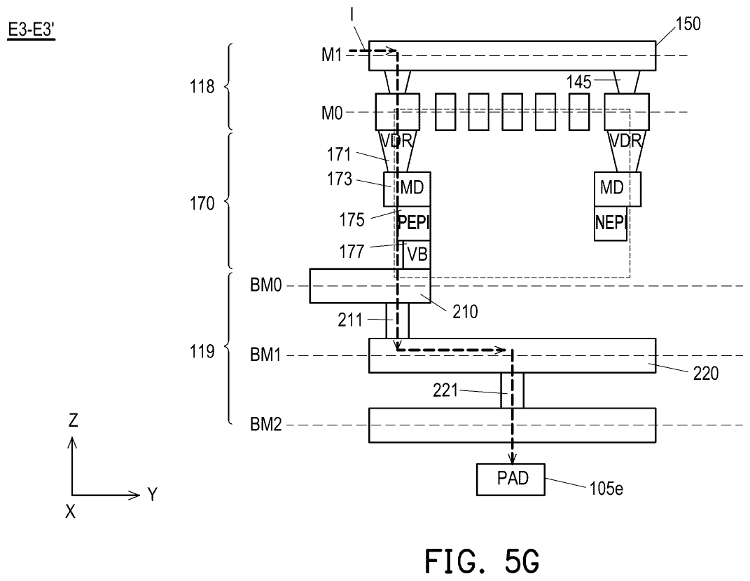

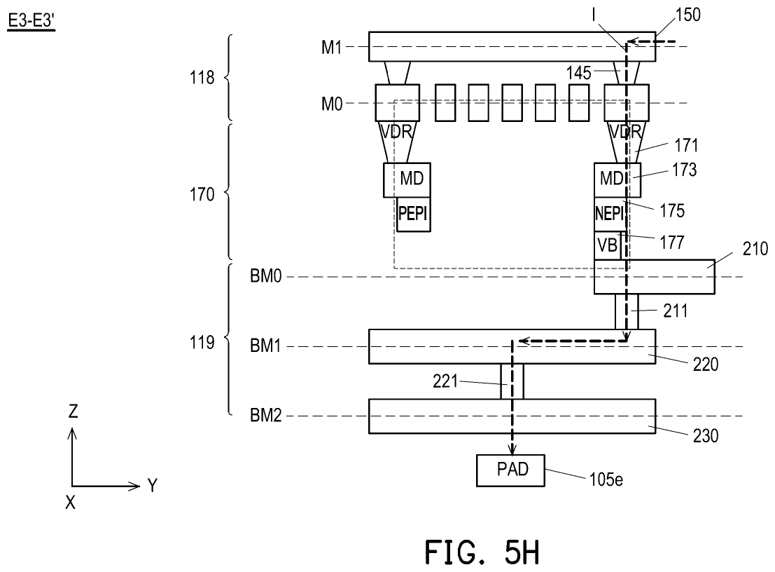

Reference is made to FIGS. 5A-5H. FIGS. 5A and 5B illustrate top view layout patterns of an I/O circuit 101e including a buffer circuit 103e with an ESD protection circuit 104e in accordance with some embodiments of the present disclosure. FIG. 5C illustrates a schematic cross-sectional view of the I/O circuit 101e including the buffer circuit 103e with the ESD protection circuit 104e. FIG. 5D illustrates a cross-sectional view of the I/O circuit 101e obtained from a reference cross-sectional E1-E1′ in FIG. 5A in accordance with some embodiments of the present disclosure. FIG. 5E illustrates a cross-sectional view of the I/O circuit 101e obtained from a reference cross-sectional E2-E2′ in FIG. 5A in accordance with some embodiments of the present disclosure. FIGS. 5F-5H illustrate cross-sectional views of the I/O circuit 101e obtained from a reference cross-sectional E3-E3′ in FIG. 5B in accordance with some embodiments of the present disclosure.

Reference is made to FIGS. 5A-5C. The buffer circuit 103e and the ESD protection circuit 104e of the I/O circuit 101e can correspond to the buffer circuit 103a and the ESD protection circuit 104a of the I/O circuit 101a, as illustrated in FIGS. 2A and 3A-3K. For simplicity, corresponding components of the I/O circuits 101a and 101e are designated by the same reference numerals. Each of the ESD protection circuit 104e and the buffer circuit 103e includes a plurality of transistors 110. Details of the transistors 110 can be found in FIGS. 2A and 3A-3K. The buffer circuit 103e comprises two sub-buffer circuit regions (e.g. a first buffer circuit region 10B and a second buffer circuit region 10C) on a substrate 50 (see FIG. 5C). The ESD protection circuit 104e is formed over an ESD protection circuit region 10A on the substrate 50. The ESD protection circuit region 10A is located between the first and second buffer circuit regions 10B and 10C along the X-direction. Source/drain terminals of the transistors 110 of the buffer circuit 103a and the ESD protection circuit 104a are formed over source/drain regions on the substrate 50.

In some embodiments, a frontside interconnect structure 118 (see FIG. 5C) is formed over the transistors 110 and includes, for example, seven metallization layers disposed along the Z-direction. Three metallization layers, labeled M0, M1, and M2, are depicted in FIG. 5C. Metal lines 140 and 142 at the M0 level (see FIG. 5A) extend along the X-direction, while a metal line 150 at the M1 level (see FIG. 5A) extends along the Y-direction. The metal line 140 at the M0 level is electrically coupled to the drain terminals of the source/drain regions (S/D) in the first and second buffer circuit regions 10B and 10C through source/drain contacts 120 and source/drain vias 130. The metal line 142 at the M0 level is electrically connected to gate structures 112 in the first and second buffer circuit regions 10B and 10C through gate vias 132 (see FIGS. 5A and 5C).

A signal transmission path (designated with dotted arrow lines as signal I in the drawings) is established between the ESD protection circuit region 10A and the first and second buffer circuit regions 10B and 10C through the metal line 140. The source/drain regions S/D of the first and second buffer circuit regions 10B and 10C are electrically coupled to the source/drain regions of the ESD protection circuit region 10A through the metal line 140, which extends in the X-direction. To mitigate stress caused by electromigration, a higher-level metal line, such as metal line 160 at the M2 level, may be employed in conjunction with the metal line 140 at the M0 level for signal transmission between the ESD protection circuit region 10A and the first and second buffer circuit regions 10B and 10C. The metal line 160 at the M2 level extends in the X-direction and spans across the ESD protection circuit region 10A and the first and second buffer circuit regions 10B and 10C.

The I/O circuit 101e further includes a backside interconnect structure 119 formed beneath the substrate 50 (see FIG. 5C). The backside interconnect structure 119 includes a plurality of metallization layers. Three metallization layers, labeled BM0,BM1, and BM2, are depicted in FIG. 5C. An isolation layer (not shown) may be disposed between the metallization layers. In some embodiments, the backside interconnect structure 119 may include additional layers, such as six metallization layers. Metal lines in the metallization layers of the backside interconnect structure 119 are electrically connected by vias disposed therebetween. For example, a metal line 210 at the BM0 level and a metal line 220 at the BM1 level are electrically connected by vias 211. Similarly, the metal line 220 at the BM1 level and a metal line 230 at the BM2 level are electrically connected by vias 221. The backside interconnect structure 119 further comprises various interlayer dielectric layers (not shown) in which the metallization layers and the vias are embedded. The backside interconnect structure 119 may be electrically connected to a backside pad 105e through the metal lines 210, 220, 230, and the vias 211, 221. In some embodiments, the backside pad 105e may alternatively be referred to as a metal pad, a pad pin, or a die-to-die pad.

The backside interconnect structure 119 is electrically coupled to the ESD protection circuit region 10A through the metal line 150 at the M1 level. The signal I is transmitted from the buffer circuit regions 10B and 10C to the ESD protection circuit region 10A through the metal line 140 at the M0 level in the X-direction. Subsequently, the signal I is transmitted in the Y-direction along the metal line 150 at the M1 level from the ESD protection circuit region 10A to the backside interconnect structure 119. This arrangement diverts the current path during an ESD event to the backside interconnect structure 119, thereby reducing output capacitance loading and enhancing electromigration resilience in the frontside interconnect structure 118. It should be noted that the direction of the signal I may reverse depending on the polarity of the ESD currents (positive or negative).

Reference is made to FIGS. 5D and 5E, which are cross-sectional views of the I/O circuit 101e along the reference cross-sections E1-E1′ and E2-E2′ in FIG. 5A, in accordance with some embodiments of the present disclosure. A conductive structure 170 is located between the frontside interconnect structure 118 and the backside interconnect structure 119 along the Z-direction. The metal line 150 at the M1 level is electrically connected to the backside interconnect structure 119 by the conductive structure 170. Consequently, the ESD protection circuit region 10A is electrically coupled to the backside interconnect structure 119 through the conductive structure 170. In some embodiments, the ESD protection circuit region 10A is positioned adjacent to both the conductive structure 170 and the backside interconnect structure 119 in the Y-direction (see FIG. 5A).

In some embodiments, the conductive structure 170 includes a rail-type via-to-device (VDR) contact structure 171, a metal-to-device (MD) contact structure 173, and a backside feedthrough via (B_FTV) contact structure 179. The VDR contact structure 171 is in contact with a lower surface of the frontside interconnect structure 118 (e.g., specifically the lower surface of the metal line 140 at the M0 level. The VDR contact structure 171 may be formed of a metal or other conductive material. The MD contact structure 173 is disposed beneath and electrically connected to the VDR contact structure 171. The MD contact structure 173 may include a conductive material, such as a metal, and is formed over corresponding source/drain features of the I/O circuit 101e. The B_FTV contact structure 179 comprises a conductive material, such as a metal, and extends through the substrate 50 to electrically connect the frontside interconnect structure 118 and the backside interconnect structure 119. The B_FTV contact structure 179 is in contact with a lower surface of the MD contact structure 173 and an upper surface of the backside interconnect structure 119 (e.g., upper surface of the metal line 210 at the BM0 level).

In some embodiments, source/drain regions S/D of the ESD protection circuit region 10A can include first and second epitaxy structures 175. The first and second epitaxy structures 175 may be P-type or N-type epitaxy structures, corresponding to source/drain regions of a PMOS transistor or an NMOS transistor, respectively. In some embodiments, although the epitaxy structure 175 is configured and/or manufactured as a source/drain region, there is no gate associated with the epitaxy structure 175 to form a transistor. The B_FTV contact structure 179 is positioned between the first and second epitaxy structures 175 and is further electrically coupled to the backside pad 105e through the metal lines 210, 220, and 230, as well as vias 211 and 221 of the backside interconnect structure 119.

Reference is made to FIGS. 5F and 5H, which are cross-sectional views of the I/O circuit 101e along the reference cross-sectionals E3-E3′ in FIG. 5B in accordance with some embodiments of the present disclosure. In some embodiments, the ESD protection circuit region 10A overlaps the conductive structure 170 and the backside interconnect structure 119 in both the X-direction and Y-direction (see FIG. 5B). The conductive structure 170 may include the VDR contact structure 171, the MD contact structure 173, the epitaxy structure 175, and a backside via (VB) 177. The VDR contact structure 171 is in contact with a lower surface of the frontside interconnect structure 118 (i.e., lower surface of the metal line 140 at the M0 level). The MD contact structure 173 is disposed and electrically connected to the VDR contact structure 171. The epitaxy structure 175 is formed beneath the lower surface of the MD contact structure 173. The backside via 177 contacts the lower surface of the epitaxy structure 175 and the upper surface of the backside interconnect structure 119 (i.e., upper surface of the metal line 210 at the BM0 level). The backside via 177 is further electrically coupled to the backside pad 105e through the metal lines 210, 220, 230 and vias 211, 221 of the backside interconnect structure 119. FIG. 5F depicts two signal transmission paths flow through both a P-type epitaxy structure (designated as “PEPI” in the drawings) and an N-type epitaxy structure (designated as “NEPI” in the drawings) of the conductive structure 170. FIGS. 5G and 5H depict one signal transmission path flow through a P-type epitaxy structure or an N-type epitaxy structure of the conductive structure 170.

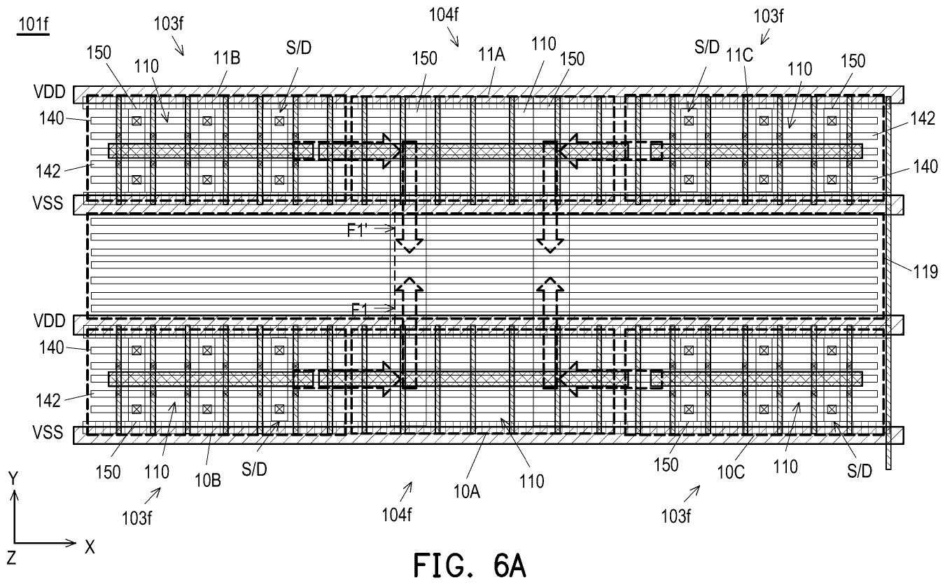

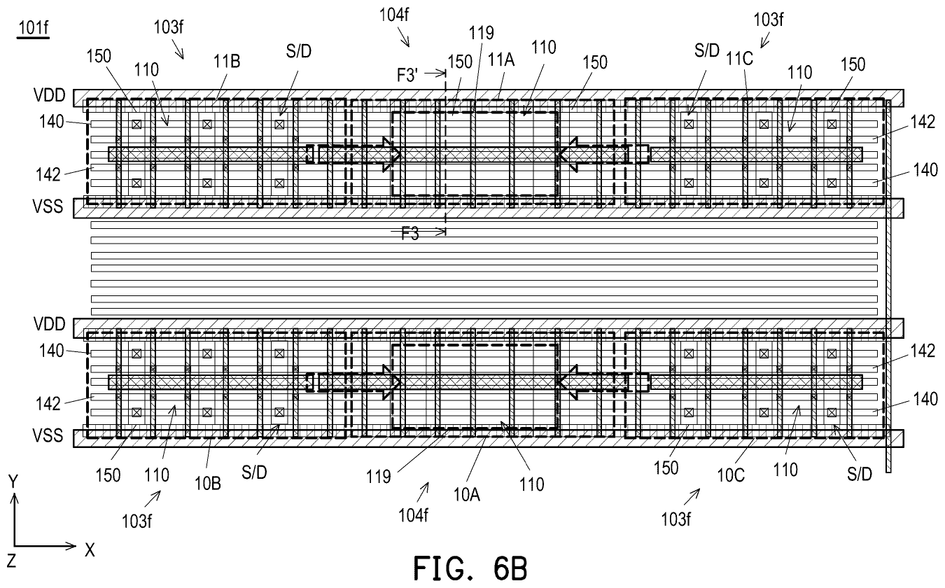

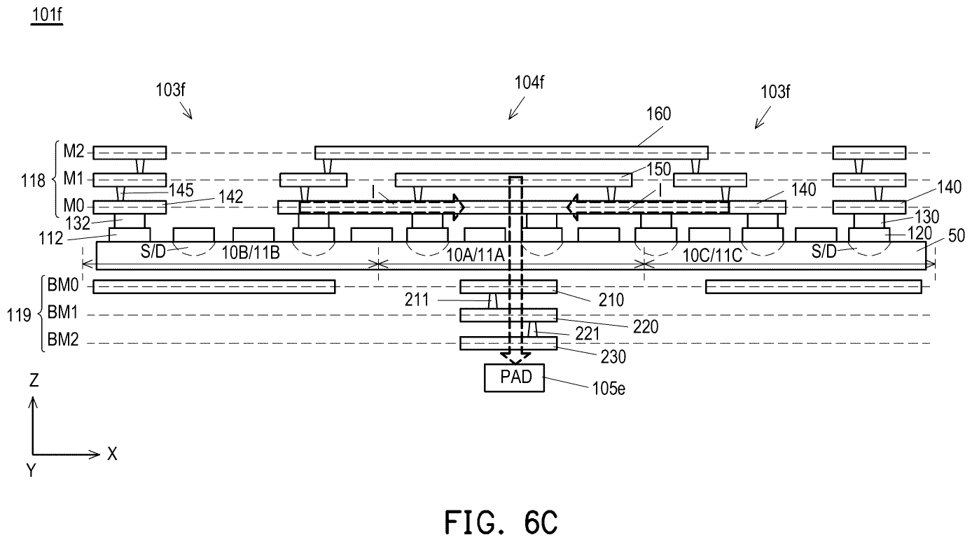

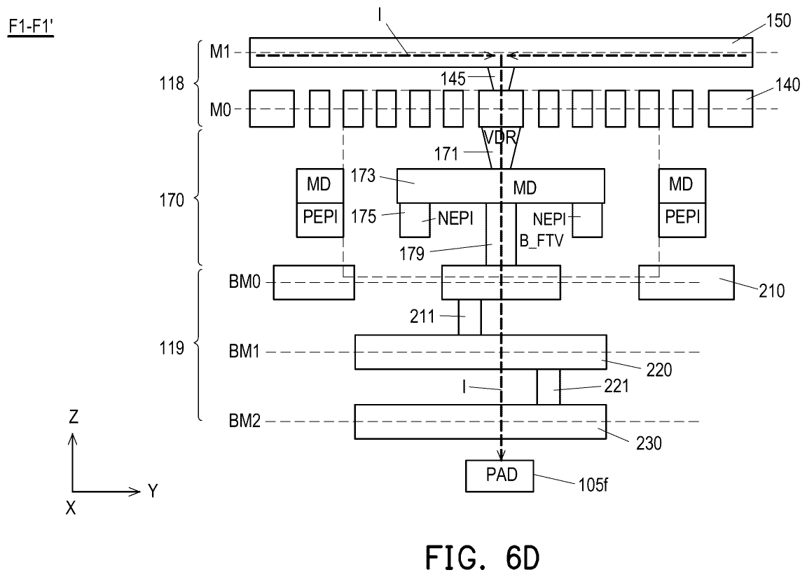

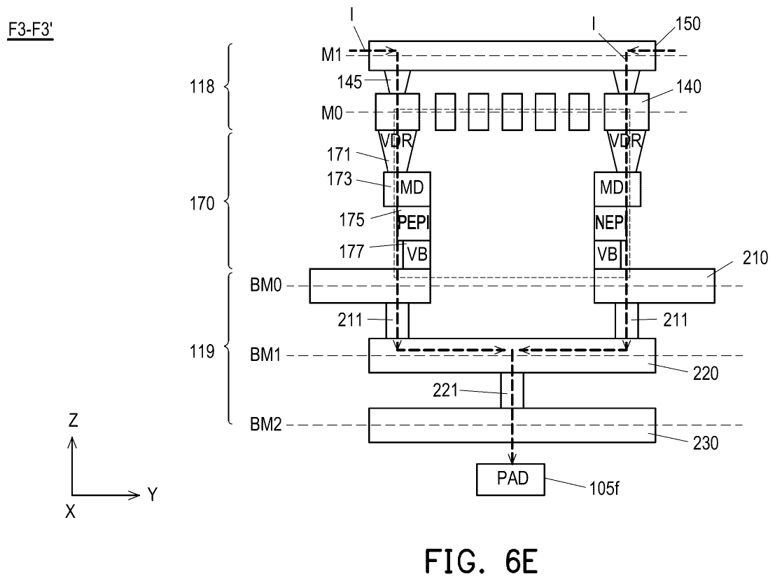

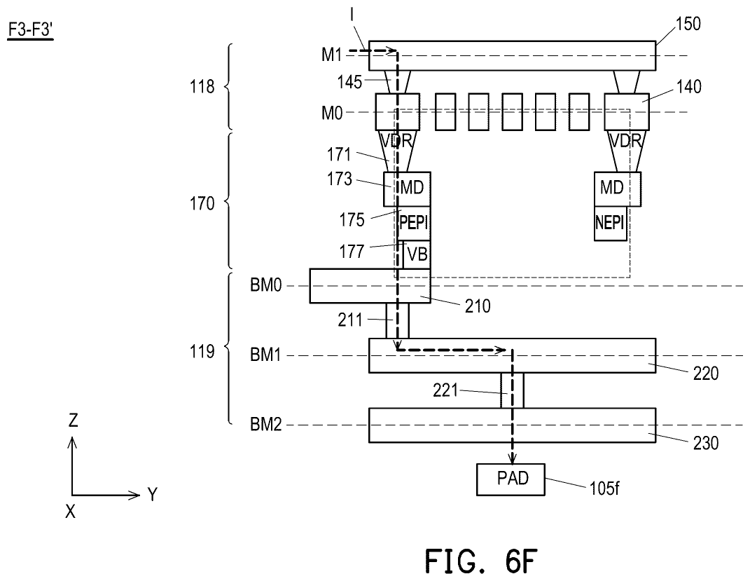

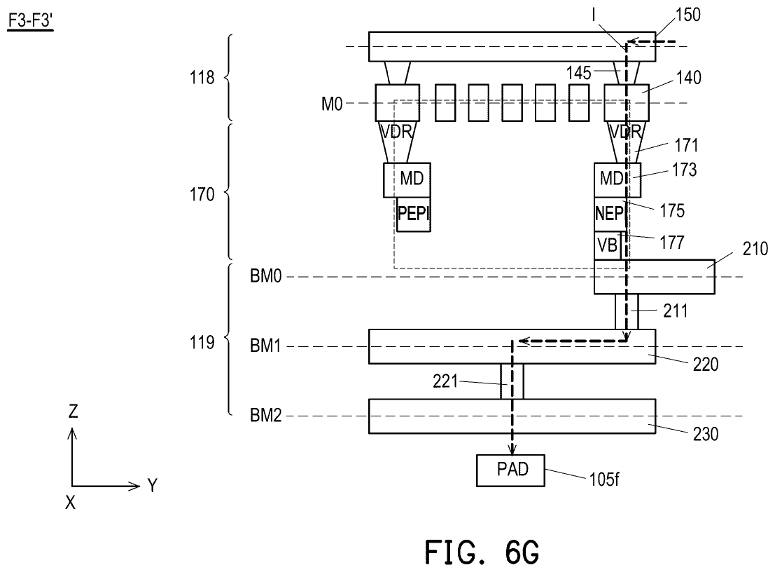

Reference is made to FIGS. 6A-6G. FIGS. 6A and 6B illustrate top view layout patterns of an I/O circuit 101f including a buffer circuit 103f with an ESD protection circuit 104f in accordance with some embodiments of the present disclosure. FIG. 6C illustrates a schematic cross-sectional view of the I/O circuit 101f including the buffer circuit 103f with the ESD protection circuit 104f. FIG. 6D illustrates a cross-sectional view of the I/O circuit 101f obtained from a reference cross-sectional F1-F1′ in FIG. 6A in accordance with some embodiments of the present disclosure. FIGS. 6F-6G illustrate cross-sectional views of the I/O circuit 101f obtained from a reference cross-sectional F3-F3′ in FIG. 6B in accordance with some embodiments of the present disclosure.

Reference is made to FIGS. 6A-6C. The buffer circuit 103f and the ESD protection circuit 104f of the I/O circuit 101f can correspond to the buffer circuit 103e and the ESD protection circuit 104e of the I/O circuit 101e as shown in FIGS. 5A-5C. For simplicity, corresponding components of the I/O circuits 101e and 101f ar edesignated by the same reference numerals. The ESD protection circuit 104c is formed with two ESD protection circuit regions (i.e., a first ESD protection circuit region 10A and a second ESD protection circuit region 11A). The buffer circuit 103f are formed with four buffer circuit regions (i.e., a first buffer circuit region 10B, a second buffer circuit region 10C, a third buffer circuit region 11B, and a fourth buffer circuit region 11C). The first ESD protection circuit region 10A is located between the first and second buffer circuit regions 10B and 10C along the X-direction. The second ESD protection circuit region 11A is disposed between the third and fourth buffer circuit regions 11B and 11C along the X-direction. The ESD protection circuit regions 10A and 11A of the I/O circuit 101f are similar to the ESD protection circuit regions 10A of the I/O circuit 101e. The buffer circuit regions 10B, 10C, 11B, and 11C of the I/O circuit 101f can correspond to the buffer circuit regions 10B and 10C of the I/O circuit 101e. Since the buffer circuit 103f are divided into four sub-buffer circuit regions, the horizontal current in the metal lines 140 at the M0 level can be split into four transmission paths. This arrangement can further alleviate issues related to current crowding and electromigration.

In some embodiments, the backside interconnect structure 119 is disposed between the first and second ESD protection circuit regions 10A and 11A along the Y-direction. The backside interconnect structure 119 extends in a lengthwise direction parallel to the X-direction. The length of the backside interconnect structure 119 may be greater than the lengths of the first and second ESD protection circuit regions 10A and 11A, extending across the buffer circuit regions 10B, 10C, 11B, and 11C. The horizontal current from the buffer circuit 103f to the ESD protection circuit 104f can be divided into four signal transmission paths in the X-direction. As a result, only the metal lines 140 at the M0 level are used for signal transmission in the X-direction, and no metal lines at higher levels are required for signal transmission between the ESD protection circuit 104f and the buffer circuit 103f.

The first ESD protection circuit region 10A is electrically coupled to the first and second buffer circuit regions 10B and 10C through a first group of metal lines 140 at the M0 level in the X-direction. The first ESD protection circuit region 10A is also electrically coupled to the backside interconnect structure 119 through metal lines 150 at the M1 level in the Y-direction. Similarly, the second ESD protection circuit region 11A is electrically coupled to the third and fourth buffer circuit regions 11B and 11C through a second group of metal lines 140 at the M0 level in the X-direction. The second ESD protection circuit region 11A is electrically coupled to the backside interconnect structure 119 through metal lines 150 at the M1 level in the Y-direction. The ESD protection circuit regions 10A and 11A may also be electrically coupled to a backside pad 105f through the backside interconnect structure 119.

Reference is made to FIGS. 6D-6G. A conductive structure 170 is disposed between the frontside interconnect structure 118 and the backside interconnect structure 119 in the Z-direction. The conductive structure 170 in FIGS. 6D-6G corresponds to the conductive structure in FIGS. 5D-5H without further descriptions herein.

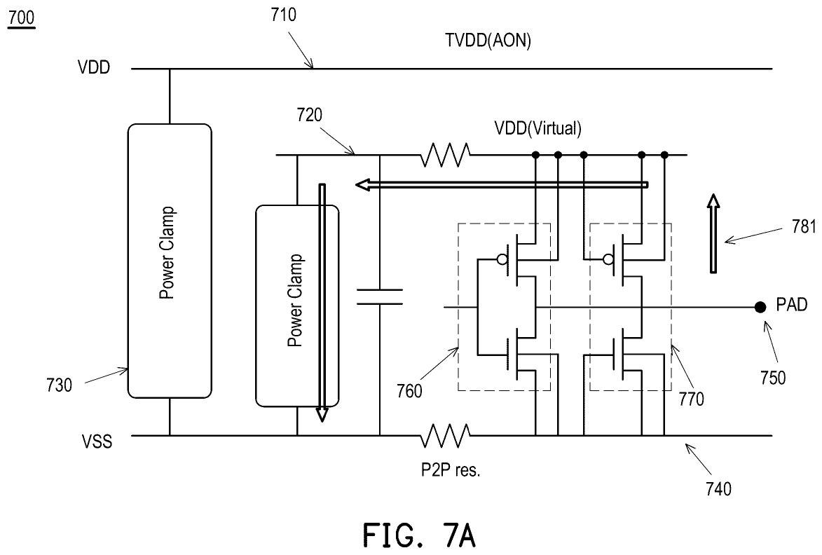

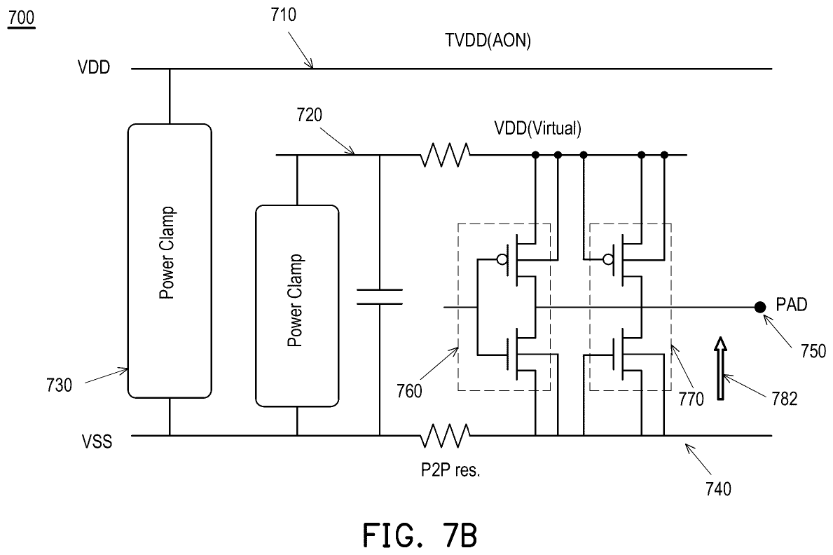

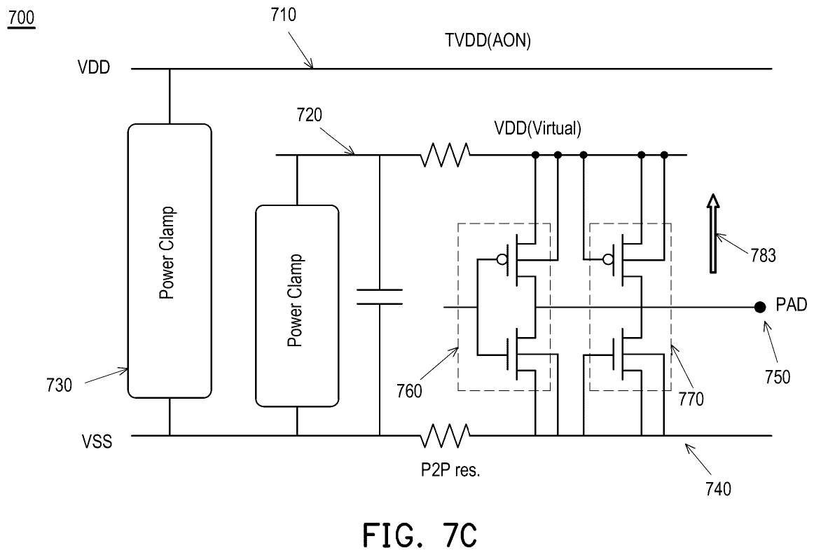

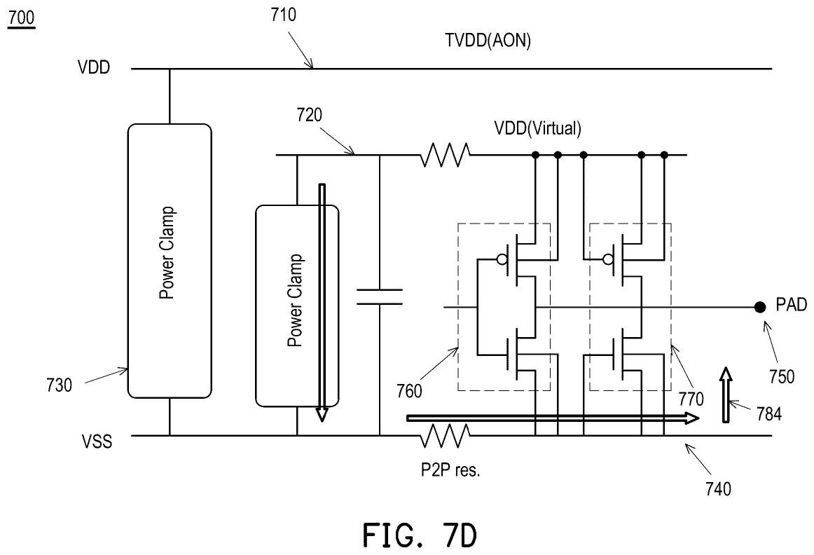

Reference is made to FIGS. 7A to 7D, which illustrate different ESD signal transmission paths in an I/O circuit 700. The I/O circuit 700 includes a power clamp 730, a buffer circuit 760, and an ESD protection circuit 770. The power clamp 730 is coupled between the power supply rails VDD and VSS and serves to protect the circuit during ESD events. The power clamp 730 is activated when a trigger voltage 710 is applied to the power supply rail VDD, causing it to clamp the voltage and prevent excessive voltage buildup. Additionally, during an ESD event, a dynamic voltage 720 is generated, which further triggers the power clamp 730 to absorb the surge and protect the circuit. The power supply rail VSS is typically connected to an electrical ground. The buffer circuit 760 is responsible for interfacing between the pad 750 and the internal circuitry. The buffer circuit 760 can include at least one pair of transistors, typically an NMOS transistor and a PMOS transistor, configured in a complementary push-pull arrangement. This configuration allows the buffer circuit 760 to efficiently drive the pad 750 with both sourcing and sinking capabilities, ensuring reliable signal transmission in both directions. The ESD protection circuit 770 may include a pair of grounded-gate transistors, such as a ggNMOS transistor and a ggPMOS transistor. These transistors are configured to clamp the voltage during an ESD event, diverting the excess current to ground and preventing it from damaging the buffer circuit 760 or other sensitive internal components.

During ESD events, the power supply rails VDD and VSS can experience transient voltage surges or drops, which are categorized into four types of signals. A positive VSS (PS) signal 781 indicates a transient voltage surge where the VSS rail 740 momentarily rises to a positive potential relative to its normal ground state. This can occur due to an external electrostatic charge or a sudden redistribution of charge within the circuit. Conversely, a negative VSS (NS) signal 782 represents a transient voltage drop where the VSS rail 740 falls below its normal ground potential.

Similarly, a positive VDD (PD) signal 783 occurs when the VDD rail 710, which is the primary positive power supply, experiences a transient voltage surge and rises above its normal operating value. This type of surge is common when external energy is injected into the system, such as through contact or proximity to a charged object. A negative VDD (ND) signal 784 reflects a transient voltage drop where the VDD rail 710 dips below its normal positive potential. FIGS. 7A to 7D illustrate the respective discharge paths for the PS signal 781, NS signal 782, PD signal 783, and ND signal 784. These discharge paths demonstrate how I/O circuit 700 redirects the transient currents associated with these signals to minimize damage.

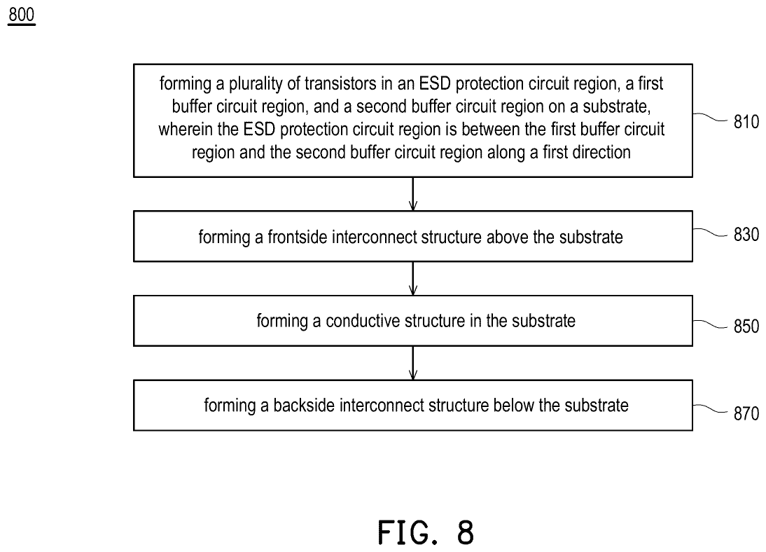

Reference is made to FIG. 8, which illustrate a flowchart depicting a method 800 of manufacturing a die-to-die IC structure including a buffer circuit with an ESD protection circuit in accordance with some embodiments of the present disclosure. It is understood that additional operations may be performed before, during, and/or after the method 800 and that some other process may only be briefly described herein.

As shown in FIG. 8, the method 800 begins with operation 810 in which a plurality of transistor are formed in an ESD protection circuit region, a first buffer circuit region, and a second buffer circuit region on a substrate. The first and the second buffer circuit regions can correspond to the buffer circuit regions 10B and 10C in FIGS. 5A-5C and 6A-6C. The first ESD protection circuit region can correspond to the ESD protection circuit region 10A in FIGS. 5A-5C and 6A-6C. The ESD protection circuit region 10A is between the first buffer circuit region 10B and the second buffer circuit region 10C along the X-direction. A first transistor of the plurality of transistors is formed in the ESD protection circuit region 10A. A second transistor of the plurality of transistors is formed in the first buffer circuit region 10B. A third transistor of the plurality of transistors is formed in the second buffer circuit region 10C. In operation 830, a frontside interconnect structure is formed above the substrate. The frontside interconnect structure corresponds to the frontside interconnect structure 118 in FIGS. 5A-5H and 6A-6G. In some embodiments, the frontside interconnect structure 118 has a first frontside metal line 140 extending in the X-direction and a second frontside metal line 150 extending in the Y-direction. The first transistor in the first ESD protection circuit region 10A is electrically coupled to the second transistor in the first buffer circuit region 10B and the third transistor in the second buffer circuit region 10C through the first frontside metal line 140. In operation 850, a conductive structure is formed in the substrate. The conductive structure can correspond to the conductive structure 170 in FIGS. 5D-5H and 6D-6G. The conductive structure 170 is electrically connected to the second frontside metal line 150. In some embodiments, the conductive structure 170 includes a VDR contact structure 171, a MD contact structure 173, and a B_FTV contact structure 179, as shown in FIGS. 5D and 5E. In some embodiments, the conductive structure 170 includes a VDR contact structure 171, a MD contact structure 173, a epitaxy structure 175, and a backside via (VB) 177, as shown in FIGS. 5F-5H. In operation 870, a backside interconnect structure is formed beneath the substrate. The backside interconnect structure can correspond to the backside interconnect structure 119 in FIGS. 5A-5H and 6A-6G. In some embodiments, the first transistor in the first ESD protection circuit region 10A is electrically coupled to the backside interconnect structure 119 through the second frontside metal line 150. The conductive structure 170 is formed between the frontside interconnect structure 118 and the backside interconnect structure 119 along the Z-direction. Thus, according to the method described above, a die-to-die IC structure including a buffer circuit with an ESD protection circuit may be formed.

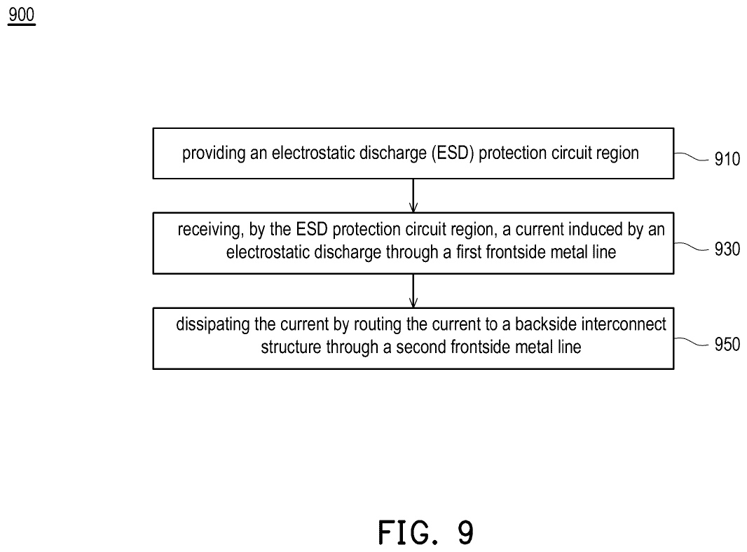

Reference is made to FIG. 9, which illustrate a flowchart depicting a method 900 of discharging an electrostatic induced current in accordance with some embodiments of the present disclosure. It is understood that additional operations may be performed before, during, and/or after the method 900 and that some other process may only be briefly described herein.

As shown in FIG. 9, the method 900 begins with operation 910 in which an electrostatic discharge (ESD) protection circuit region is provided between a first buffer circuit region and a second buffer circuit region. The ESD protection circuit region and the first and second buffer circuit regions are provided along X-direction on a substrate, and can respectively correspond to ESD protection circuit region 10A and the buffer circuit regions 10B and 10C in FIGS. 5A-5C and 6A-6C. The ESD protection circuit region may be electrically coupled to the first and second buffer circuit regions through a first frontside metal line of a frontside interconnect structure over the substrate. The ESD protection circuit region may be electrically coupled to a backside interconnect structure beneath the substrate through a second frontside metal line of the frontside interconnect structure. For example, as shown in FIGS. 5A-5C and 6A-6C, the ESD protection circuit region 10A can be electrically coupled to the buffer circuit regions 10B and 10C through the frontside metal line 140 of the frontside interconnect structure 118. The ESD protection circuit region 10A can be electrically coupled to the backside interconnect structure 119 through the frontside metal line 150 of the frontside interconnect structure 118. In operation 930, a current induced by an electrostatic discharge is received by the ESD protection circuit region through the first frontside metal line. For example, as shown in FIGS. 5A-5C and 6A-6C, the signal I induced by an ESD event can be received by the ESD protection circuit region 10A through the frontside metal line 140. In operation 950, the current is dissipated by routing the current to the backside interconnect structure through the second frontside metal line. For example, as shown in FIGS. 5A-5C and 6A-6C, the signal I can be dissipated by routing the signal I to the backside interconnect structure 119 through the frontside metal line 150. The ESD protection circuit region may be further electrically connected to the conductive structure disposed between the frontside interconnect structure and the backside interconnect structure along Z-direction. The conductive structure can be correspond to the conductive structure 170 in FIGS. 5D-5H and 6D-6G.

IC structures and methods are described herein. In an exemplary embodiment, a die-to-die input/output IC structure is provided. The die-to-die input/output IC structure comprises a first ESD protection circuit region, a frontside interconnect structure, and backside interconnect structure. The first ESD protection circuit region is disposed between a first buffer circuit region and a second buffer circuit region along a first direction on a substrate. The frontside interconnect structure is disposed over the substrate and has a first frontside metal line extending in a first direction and a second frontside metal line extending in a second direction perpendicular to the first direction. The first ESD protection circuit protection region is electrically coupled to the first and second buffer circuit regions through the first frontside metal line. The backside interconnect structure may be electrically coupled to a backside pad. the backside interconnect structure may comprise a plurality of backside metal lines and a plurality of vias. The second frontside metal line is electrically coupled to the backside pad through the plurality of backside metal lines and the plurality of vias of the backside interconnect structure.

The die-to-die input/output IC structure may comprise a conductive structure between the frontside interconnect structure and the backside interconnect structure along a third direction perpendicular to the first and second directions. the first ESD protection circuit region is electrically coupled to the backside interconnect structure through the conductive structure.

In some embodiments, the conductive comprises a rail-type via-to-device (VDR) contact structure, a metal-to-device (MD) contact structure, an epitaxy structure, and a backside via. The VDR contact structure may be in contact with a lower surface of the first frontside metal line. The MD contact structure may be positioned below and in electrically contact with the VDR contact structure. The epitaxy via may be located beneath and in electrically contact with the MD contact structure. The backside via may be in contact with a lower surface of the epitaxy structure and an upper surface of the backside interconnect structure. The first ESD protection circuit region may overlap the conductive structure and the backside interconnect structure in the third direction. The epitaxy structure may be a P-type epitaxy structure or an N-type epitaxy structure.

In some embodiments, a die-to-die input/output IC structure may further comprise a second ESD protection circuit region disposed between a third buffer circuit region and a fourth buffer circuit region along the first direction. The second ESD protection circuit region may be electrically coupled to the third and fourth buffer circuit regions through a third frontside metal line of the frontside interconnect structure that extends in the first direction. The second ESD protection circuit region may be electrically coupled to the backside interconnect structure through the second frontside metal line. The backside interconnect structure may be disposed between the first and second ESD protection circuit regions along the second direction. The backside interconnect structure may include a first backside interconnect sub-structure and a second backside interconnect sub-structure. The first ESD protection circuit region may overlap the first backside interconnect sub-structure in a third direction perpendicular to the first and second directions. The second ESD protection circuit region may overlap the second backside interconnect sub-structure in the third direction.

In some embodiments, the conductive structure comprises a VDR contact structure, a MD contact structure, and a backside feedthrough via (B_FTV) contact structure. The VDR contact structure may be in contact with a lower surface of the first frontside metal line. The MD contact structure may be positioned beneath the VDR contact structure. The B_FTV contact structure may be in contact with a lower surface of the MD contact structure and an upper surface of the backside interconnect structure. the first ESD protection circuit region is adjacent to the conductive structure and the backside interconnect structure in the third direction. The first ESD protection circuit further comprises first and second epitaxy structures. The B_FTV contact structure may be disposed between the first and second epitaxy structures along the second direction.

In an exemplary embodiment, a die-to-die input/output IC structure is provided. The die-to-die input/output IC structure comprises a first transistor, a second transistor, a third transistor, a frontside interconnect structure, and a backside interconnect structure. The first transistor may be formed over a first ESD protection circuit region of a substrate. The second transistor may be formed over a first buffer circuit region of the substrate. The third transistor may be formed over a second buffer circuit region of the substrate. The frontside interconnect structure may be formed over the substrate and have a first frontside metal line extending in a first direction and a second frontside metal line extending in a second direction perpendicular to the first direction. The first transistor may be coupled to the second and third transistors through the first frontside metal line. The backside interconnect structure may be formed beneath the substrate. The first transistor may be coupled to a backside pad of the backside interconnect structure through the second frontside metal line.

In some embodiments, the first frontside metal line may be electrically connected to source/drain regions in the first and second buffer circuit regions through source/drain contacts and source/drain vias. The second and third transistors may have source/drain terminals located in the source/drain regions of the first and second buffer circuit regions.

In some embodiments, the die-to-die input/output IC structure may further comprises a fourth transistor, a fifth transistor, and a sixth transistor. The fourth transistor may be formed over a second ESD protection circuit region of the substrate. The fifth transistor may be formed over a third buffer circuit region of the substrate. The sixth transistor may be formed over a fourth buffer circuit region of the substrate. The fourth transistor may be coupled to the fifth and sixth transistor through the first frontside metal line. The fourth transistor may be coupled the backside pad of the backside interconnect structure through the second frontside metal line.

In an exemplary embodiment, a method of manufacturing a die-to-die input/output integrated circuit (IC) structure is provided. A plurality of transistors are formed in an ESD protection circuit region, a first buffer circuit region, and a second buffer circuit region on a substrate. A first transistor of the plurality of transistors is formed in the ESD protection circuit region. A second transistor of the plurality of transistors is formed in the first buffer circuit region. A third transistor of the plurality of transistors is formed in the second buffer circuit region. The ESD protection circuit region is between the first buffer circuit region and the second buffer circuit region along a first direction. A frontside interconnect structure is formed above the substrate. The frontside interconnect structure has a first frontside metal line extending in the first direction and a second frontside metal line extending in a second direction perpendicular to the first direction. The first transistor in the ESD protection circuit region is electrically connected to the second transistor in the first buffer circuit region and the third transistor in the second buffer circuit region through the first frontside metal line. A conductive structure is formed in the substrate. The conductive structure is electrically connected to the second frontside metal line. A backside interconnect structure is formed below the substrate. The first transistor in the ESD protection circuit region is electrically connected to the backside interconnect structure through the second frontside metal line. In some embodiments, the conductive structure is between the frontside interconnect structure and the backside interconnect structure along a third direction perpendicular to the first and second directions. The first transistor in the ESD protection circuit region is electrically connected to the backside interconnect structure through the conductive structure.

In an exemplary embodiment, a method of discharging an electrostatic induced current is provided. An ESD protection circuit regions is provided between first and second buffer circuit regions along a first direction on a substrate. The ESD protection circuit region is electrically coupled to the first and second buffer circuit regions through a first frontside metal line of a frontside interconnect structure over the substrate. The ESD protection circuit region is further electrically coupled to a backside interconnect structure beneath the substrate through a second frontside metal line of the frontside interconnect structure. A current induced by an electrostatic discharge is received by the ESD protection circuit region through the first frontside metal line. The current is dissipated by routing the current to the backside interconnect structure through the second frontside metal line. In some embodiments, the first frontside metal line extends in the first direction, and the second frontside metal line extends in a second direction perpendicular to the first direction. The ESD protection circuit region is further electrically coupled to a conductive structure between the frontside interconnect structure and the backside interconnect structure along a third direction perpendicular to the first and second directions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A die-to-die input/output integrated circuit (IC) structure, comprising:
a first electrostatic discharge (ESD) protection circuit region between a first buffer circuit region and a second buffer circuit region along a first direction on a substrate;
a frontside interconnect structure over the substrate and having a first frontside metal line extending in the first direction and a second frontside metal line extending in a second direction perpendicular to the first direction, wherein the first ESD protection circuit region is electrically coupled to the first and second buffer circuit regions through the first frontside metal line; and
a backside interconnect structure beneath the substrate, wherein the first ESD protection circuit region is electrically coupled to the backside interconnect structure through the second frontside metal line.

2. The IC structure of claim 1, further comprising a conductive structure between the frontside interconnect structure and the backside interconnect structure along a third direction perpendicular to the first and second directions, wherein the first ESD protection circuit region is electrically coupled to the backside interconnect structure through the conductive structure.

3. The IC structure of claim 2, wherein the conductive structure comprises:
a rail-type via-to-device (VDR) contact structure in contact with a lower surface of the first frontside metal line;
a metal-to-device (MD) contact structure beneath the VDR contact structure;
an epitaxy structure beneath the MD contact structure; and
a backside via in contact with a lower surface of the epitaxy structure and an upper surface of the backside interconnect structure,
wherein the first ESD protection circuit region overlaps the conductive structure and the backside interconnect structure in the third direction.

4. The IC structure of claim 3, wherein the epitaxy structure is a P-type epitaxy structure or an N-type epitaxy structure.

5. The IC structure of claim 2, wherein the conductive structure comprising:
a VDR contact structure in contact with a lower surface of the first frontside metal line;
a MD contact structure beneath the VDR contact structure; and
a backside feedthrough via (B_FTV) contact structure in contact with a lower surface of the MD contact structure and an upper surface of the backside interconnect structure,
wherein the first ESD protection circuit region is adjacent to the conductive structure and the backside interconnect structure in the third direction.

6. The IC structure of claim 5, wherein the first ESD protection circuit further comprises first and second epitaxy structures, the B_FTV contact structure is disposed between the first and second epitaxy structures along the second direction.

7. The IC structure of claim 1, wherein the backside interconnect structure is electrically connected to a backside pad.

8. The ID structure of claim 7, wherein the backside interconnect structure comprises:
a plurality of backside metal lines; and
a plurality of vias, wherein the second frontside metal line is electrically coupled to the backside pad through the plurality of backside metal lines and the plurality of vias of the backside interconnect structure.

9. The IC structure of claim 1, wherein the first frontside metal line is positioned over or beneath the second frontside metal line in the third direction.

10. The IC structure of claim 1, further comprising:
a second ESD protection circuit region between a third buffer circuit region and a fourth buffer circuit region along the first direction,
wherein the second ESD protection circuit region is electrically coupled to the third and fourth buffer circuit regions through a third frontside metal line of the frontside interconnect structure that extends in the first direction, and the second ESD protection circuit region is electrically coupled to the backside interconnect structure through the second frontside metal line.

11. The IC structure of claim 10, wherein the backside interconnect structure disposed between the first and second ESD protection circuit regions along the second direction.

12. The IC structure of claim 10, wherein the backside interconnect structure includes a first backside interconnect sub-structure and a second backside interconnect sub-structure, the first ESD protection circuit region overlaps the first backside interconnect sub-structure in a third direction perpendicular to the first and second directions, and the second ESD protection circuit region overlaps the second backside interconnect sub-structure in the third direction.

13. A die-to-die input/output integrated circuit (IC) structure, comprising:
a first transistor over a first electrostatic discharge (ESD) protection circuit region of a substrate;
a second transistor over a first buffer circuit region of the substrate;
a third transistor over a second buffer circuit region of the substrate;
a frontside interconnect structure over the substrate and having a first frontside metal line extending in a first direction and a second frontside metal line extending in a second direction perpendicular to the first direction, wherein the first transistor is coupled to the second and third transistors through the first frontside metal line; and
a backside interconnect structure beneath the substrate, wherein the first transistor is coupled to a backside pad of the backside interconnect structure through the second frontside metal line.

14. The IC structure of claim 13, wherein the first frontside metal line is electrically coupled to source/drain regions in the first and second buffer circuit regions through source/drain contacts and source/drain vias, the second and third transistors have source/drain terminals located in the source/drain regions of the first and second buffer circuit regions.

15. The IC structure of claim 13, further comprising a conductive structure between the frontside interconnect structure and the backside interconnect structure along a third direction perpendicular to the first and second directions, wherein the first transistor is coupled to the backside pad of the backside interconnect structure through the conductive structure.

16. The IC structure of claim 1, further comprising:
a fourth transistor over a second ESD protection circuit region of the substrate;
a fifth transistor over a third buffer circuit region of the substrate; and
a sixth transistor over a fourth buffer circuit region of the substrate,
wherein the fourth transistor is coupled to the fifth and sixth transistor through the first frontside metal line, and the fourth transistor is coupled the backside pad of the backside interconnect structure through the second frontside metal line.

17. A method of manufacturing a die-to-die input/output integrated circuit (IC) structure, comprising:
forming a plurality of transistors in a first buffer circuit region, a second buffer circuit region, and an ESD protection circuit region on a substrate, wherein the ESD protection circuit region is between the first buffer circuit region and the second buffer circuit region along a first direction;
forming a frontside interconnect structure above the substrate, wherein the frontside interconnect structure has a first frontside metal line extending in the first direction and a second frontside metal line extending in a second direction perpendicular to the first direction, and a first transistor of the plurality of transistors in the ESD protection circuit region is electrically connected to a second transistor of the plurality of transistors in the first buffer circuit region and a third transistor of the plurality of transistors in the second buffer circuit region through the first frontside metal line; and
forming a backside interconnect structure below the substrate, wherein the first transistor in the ESD protection circuit region is electrically connected to the backside interconnect structure through the second frontside metal line.

18. The method of claim 17, further comprising:
forming a conductive structure in the substrate, wherein the conductive structure is electrically connected to the second frontside metal line, the conductive structure is between the frontside interconnect structure and the backside interconnect structure along a third direction perpendicular to the first and second directions, and the first transistor in the ESD protection circuit region is electrically connected to the backside interconnect structure through the conductive structure.

19. The method of claim 18, wherein the conductive structure comprises:
a rail-type via-to-device (VDR) contact structure in contact with a lower surface of the first frontside metal line;
a metal-to-device (MD) contact structure beneath the VDR contact structure; and
a backside feedthrough via (B_FTV) contact structure in contact with a lower surface of the MD contact structure and an upper surface of the backside interconnect structure,
wherein the ESD protection circuit region is adjacent to the conductive structure and the backside interconnect structure in the third direction.

20. The method of claim 18, wherein the conductive structure comprises:
a VDR contact structure in contact with a lower surface of the first frontside metal line;
a MD contact structure beneath the VDR contact structure;
an epitaxy structure beneath the MD contact structure; and
a backside via in contact with a lower surface of the epitaxy structure and an upper surface of the backside interconnect structure,
wherein the ESD protection circuit region overlaps the conductive structure and the backside interconnect structure in the third direction.
